(19) United States
(12) Patent Application Publication
(10) Pub. No.: US 2025/0366152 A1
(43) Pub. Date: Nov. 27, 2025

(54) SEMICONDUCTOR STRUCTURES AND METHODS AVOIDING CONTACT LEAKAGE

(71) Applicant: Taiwan Semiconductor Manufacturing Company, Ltd., Hsinchu (TW)

(72) Inventors: Tzu-Ging Lin, Kaohsiung (TW); Chieh-Ning Feng, Taichung (TW); Yih-Ann Lin, Jhudong (TW)

(73) Assignee: Taiwan Semiconductor Manufacturing Company, Ltd., Hsinchu (TW)

(21) Appl. No.: 18/673,942

(22) Filed: May 24, 2024

(51) Int. Cl. H01L 21/8238; H01L 27/092; H01L 29/417

(52) U.S. Cl. CPC H10D 84/038; H10D 30/6219; H10D 84/0186; H10D 84/0188; H10D 84/0193; H10D 84/853

(57) ABSTRACT

Semiconductor structures and methods of fabrication are provided. A semiconductor structure includes a first and second gate distanced from one another in a first direction, wherein each gate extends in a second direction perpendicular to the first direction; an insulation feature distanced from the first gate and the second gate in the first direction, wherein the insulation feature extends in the second direction from a first line end to a second line end; a first contact located between the first gate and the insulation feature and a second contact located between the second gate and the insulation feature; wherein each contact extends in the first direction, terminates at a first contact end, and terminates at a second contact end; the first contact ends define a first vertical plane that intersects the insulation feature; and the second contact ends define a second vertical plane that intersects the insulation feature.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a top-down schematic layout view of a semiconductor structure;

FIG. 2 illustrates a top-down schematic layout view of a portion of the semiconductor structure of FIG. 1, according to some embodiments.

FIGS. 3-30 illustrate the portion of semiconductor structure of FIG. 2 at various stages of fabrication, according to some embodiments.

FIG. 31 is a flow chart of a method for forming the structure of FIG. 2, according to some embodiments.

FIG. 32 illustrates a top-down schematic layout view of a portion of the semiconductor structure of FIG. 1, according to some embodiments.

FIGS. 33-60 illustrate the portion of semiconductor structure of FIG. 32 at various stages of fabrication, according to some embodiments.

FIG. 61 is a flow chart of a method for forming the structure of FIG. 32, according to some embodiments.

FIG. 62 and FIG. 63 are focused views of a portion of the semiconductor structure of FIG. 38, according to some embodiments.

FIG. 64 is a transmission electron microscope (TEM) image of a portion of the semiconductor device of FIG. 2, according to some embodiments.

FIG. 65 is a transmission electron microscope (TEM) image of a portion of the semiconductor device of FIG. 2, according to some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material structure” is a structure that includes at least 50 wt. % of the identified material, for example at least 60 wt. % of the identified material, at least 75 wt. % of the identified material, at least 90 wt. % of the identified material, at least 95 wt. % of the identified material, or at least 100 wt. % of the identified material; and a structure that is formed of a “material” includes at least 50 wt. % of the identified material, for example at least 60 wt. % of the identified material, at least 75 wt. % of the identified material, at least 90 wt. % of the identified material, at least 95 wt. % of the identified material, or at least 100 wt. % of the identified material. For example, certain embodiments, each of a tungsten structure and a structure formed of tungsten is a structure that is at least 50 wt. %, at least 60 wt. %, at least 75 wt. %, at least 90 wt. %, at least 95 wt. %, or at least 100 wt. % of tungsten.

For the sake of brevity, typical techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many typical processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Presented herein are embodiments of semiconductor devices and of methods for fabricating such devices. Methods described herein may be easily integrated into the current process flow. Further, methods described herein relate to the formation of an insulation structure, such as a Continuous Poly On Diffusion Edge (CPODE) structure or a Continuous Metal On Diffusion Edge (CMODE) structure, that divides a fin in two and/or a gate in two. In certain embodiments, a portion of a selected fin structure is removed and replaced with insulation material.

In embodiments herein, CMODE processing methods, i.e., formation of the insulation feature after metal gate formation, or CPODE processing methods, i.e., after before metal gate formation, are provided. In certain embodiments, dielectric structures such cut-poly gate dielectric structures, cut-metal gate dielectric structures, or dummy fins form sidewalls of the cavity etched during the CMODE or CPODE process. Thus, the insulation feature is formed in contact with the dielectric structures. In other embodiments, the insulation features directly contacts remaining gate segments.

Embodiments of the present disclosure offer advantages over the existing art, though it is understood that other embodiments may offer different advantages, not all advantages are necessarily discussed herein, and no particular advantage is required for all embodiments.

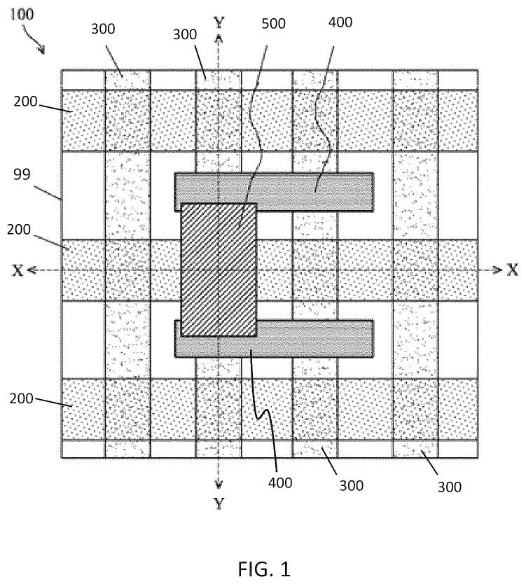

FIG. 1 illustrates a top-down schematic layout view of a semiconductor device or structure 100, such as a FinFET semiconductor device, according to some embodiments. In other embodiments a gate-all-around (GAA) semiconductor device may be formed as structure 100. In FIG. 1, the structure 100 may include a semiconductor substrate 99, semiconductor structures 200, such as fins, formed from the substrate 99, and a plurality of gates 300 formed over the fins 200. FIG. 1 further illustrates a plurality of dielectric structures 400 cut through two of the gates 300 and an insulation feature 500 dividing one of the fins 200 in two and intersecting a gate 300 and abutting the dielectric structures 400.

As shown, the fins 200 extend in the lateral X-direction and are spaced apart from one another in the lateral Y-direction, perpendicular to the lateral X-direction. Further, the gates 300 extend in the lateral Y-direction and are spaced apart from one another in the lateral X-direction, perpendicular to the lateral Y-direction. Also, the dielectric structures 400 extend in the lateral X-direction and are spaced apart from one another in the lateral Y-direction, perpendicular to the lateral X-direction. As shown, the insulation feature 500 extends in the lateral Y-direction.

It is noted that the structure 100 may include any suitable number of fins 200 to form the desired semiconductor device. Furthermore, any suitable number of gates 300, dielectric structures 400 and insulation features 500 may be formed to form the desired semiconductor device 100.

FIG. 2 illustrates a top-down schematic layout view of a portion 100′ of a semiconductor structure 100, such as the structure of FIG. 1, according to some embodiments. In FIG. 2, the schematic of the portion 100′ of structure 100 illustrates an insulation feature 500 extending in the Y-direction from a first line end 511 to a second line end 512. Each line end 511 and 512 abuts a respective dielectric structure 400. Specifically, the first line end 511 abuts a first vertically-extending dielectric structure 401 and the second line end 512 abuts a second vertically-extending dielectric structure 402. In certain embodiments, each line end 511 and 512 extends in the X-direction. As shown, the insulation feature 500 has a first sidewall 521 and a second sidewall 522 that each extend in the Y-direction. The dielectric structures 401 and 402 extend in the X-direction and are distanced from one another in the Y-direction.

The insulation feature 500 is located between a first gate 301 and a second gate 302. Each gate 301 and 302 extends between, and is interrupted by, the dielectric structures 401 and 402.

As further shown, source/drain contacts 600 are formed laterally adjacent to the insulation feature 500. Specifically, a first source/drain contact 601 is located between the first gate 301 and the insulation feature 500 and a second source/drain contact 601 is located between the second gate 302 and the insulation feature 500.

Each source/drain contact 600 extends in the Y-direction and terminates at a first contact end 611 and at a second contact end 612. Further, the first contact ends 611 define a first vertical plane 6110 perpendicular to a plane defined by the X and Y axes. As shown, the first vertical plane 6110 intersects the insulation feature 500. Likewise, the second contact ends 612 define a second vertical plane 6120 perpendicular to the plane defined by the X and Y axes. As shown, the second vertical plane 6120 intersects the insulation feature 500. More specifically, each vertical plane 6110 and 6120 intersects the sidewalls 521 and 522 of the insulation feature 500.

In certain embodiments, the first vertical plane 6110 is distanced in the Y-direction from the first line end 511 by a selected distance D1, and the second vertical plane 6120 is distanced in the Y-direction from the second line end 512 by a selected distance D2. Without limitation to the described dimensions, in certain embodiments each selected distance D1 and D2 may independently be at least 0.1 nm, such as at least 0.2, at least 0.3, at least 0.4, at least 0.5, at least 0.6, at least 0.7, at least 0.8, at least 0.9, at least 1, at least 1.1, at least 1.2, at least 1.3, at least 1.4, at least 1.5, at least 1.6, at least 1.7, at least 1.8, at least 1.9, at least 2, at least 2.25, at least 2.5, at least 2.75, at least 3, at least 3.25, at least 3.5, at least 3.75, at least 4, at least 4.25, at least 4.5, at least 4.75, at least 5 nm, at least 6 nm, at least 7 nm, at least 8 nm, at least 9 nm, at least 10 nm, or at least 12 nm. Further, without limitation to the described dimensions, in certain embodiments, each selected distance D1 and D2 may independently be at most 0.1 nm, such as at most 0.2, at most 0.3, at most 0.4, at most 0.5, at most 0.6, at most 0.7, at most 0.8, at most 0.9, at most 1, at most 1.1, at most 1.2, at most 1.3, at most 1.4, at most 1.5, at most 1.6, at most 1.7, at most 1.8, at most 1.9, at most 2, at most 2.25, at most 2.5, at most 2.75, at most 3, at most 3.25, at most 3.5, at most 3.75, at most 4, at most 4.25, at most 4.5, at most 4.75, at most 5 nm, at most 6 nm, at most 7 nm, at most 8 nm, at most 9 nm, at most 10 nm, at most 12 nm, or at most 15 nm. Values of selected distance D1 and selected distance D2 may depend on the technology node, generation, and/or application.

Generally, an increase in the distance D1 or D2 improves prevention of current leakage around the insulation feature 500. In certain embodiments, the distance D1 and distance D2 may be selected so that the line end 511 and line end 512 are located at the middle of the dielectric structure 401 and dielectric structure 401, respectively. Thus in such embodiments, each distance D1 and D2 should be greater than half the width (in the Y-direction) of the respective dielectric structure 400. In certain embodiments, each distance D1 and D2 is greater than the distance (in the Y-direction) from the plane 6110 or 6120 to the respective dielectric structure 400.

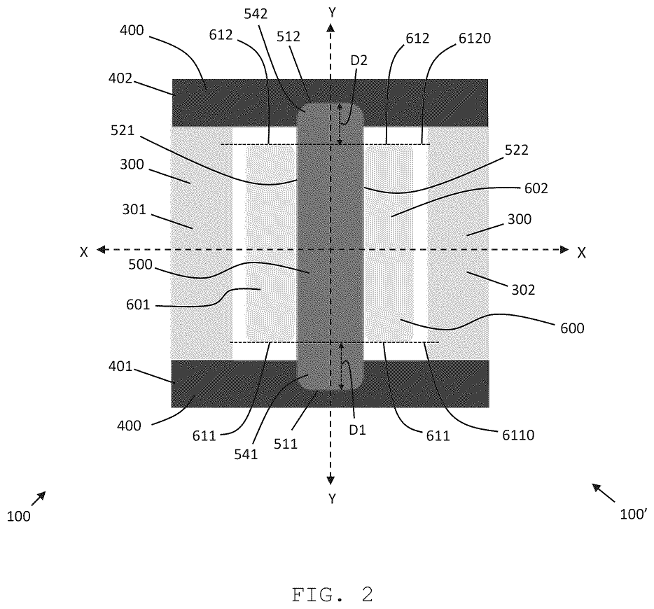

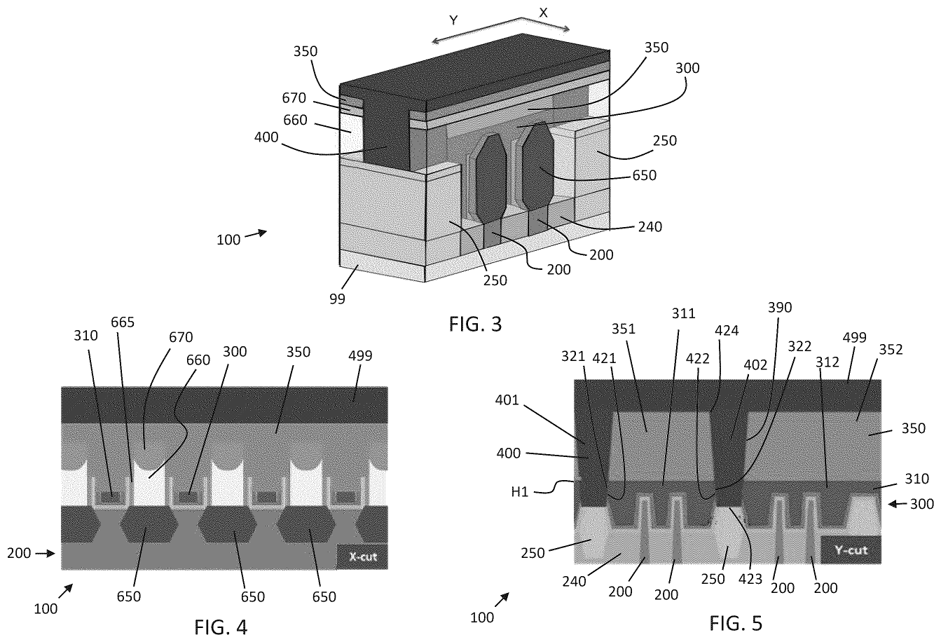

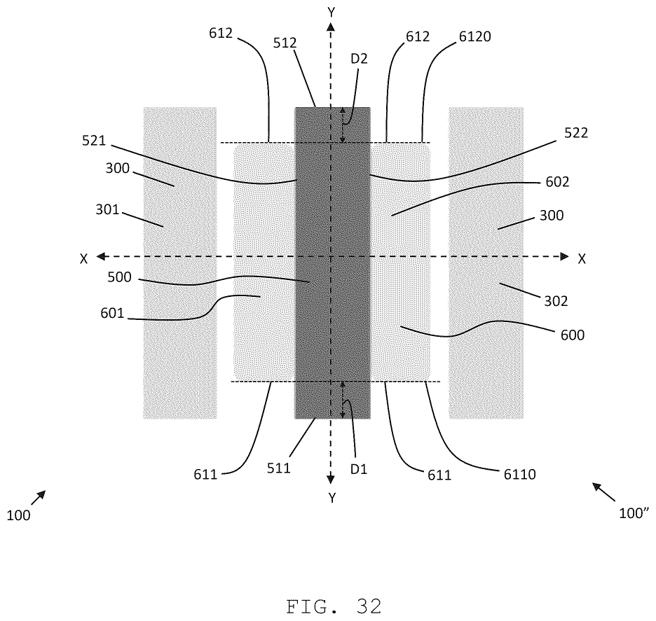

FIGS. 3-30 illustrate the portion 100′ of semiconductor structure 100 at various stages of fabrication according to the method illustrated in FIG. 31.

As shown in FIG. 31, method 1000 may begin at operation S1010 with forming a semiconductor structure 100, as shown in FIGS. 3-5. FIG. 3 is a perspective view of the semiconductor structure 100, FIG. 4 is an X-cut cross-sectional view along a fin 200, and FIG. 5 is a Y-cut cross-sectional view along a gate 300. It is noted that the perspective views presented herein may remove certain features to allow for viewing of other internally located features or for other purposes of providing clarity. While certain embodiments are described in relation to formation of a GAA structure, embodiments herein are not limited to such structures. For example, the semiconductor structure 100 may be provided as a FinFET device.

The structure 100 may be formed according to typical semiconductor processing. For example, operation S1010 may include providing a substrate 99. In some embodiments, the substrate 99 may be a semiconductor substrate such as a silicon (Si) substrate. The substrate 99 may include various layers, including conductive or insulating layers formed on a semiconductor substrate. The substrate 99 may include various doping configurations depending on design requirements as is known in the art. For example, different doping profiles (e.g., p-well, n-well) may be formed on the substrate 99 in regions designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 99 includes a single crystalline semiconductor layer on at least its surface portion. The substrate 99 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 99 may include a compound semiconductor and/or an alloy semiconductor. In the illustrated embodiment, the substrate 99 is made of crystalline Si.

Operation S1010 may include forming one or more epitaxial layers over the substrate 99. In some embodiments, an epitaxial stack is formed over the substrate 99. The epitaxial stack includes first epitaxial layers of a first composition interposed by second epitaxial layers of a second composition. The first and second composition may be different. Embodiments are possible including those that provide for a first composition and a second composition having different oxidation rates and/or etch selectivity. In an embodiment, the first epitaxial layers are silicon germanium (SiGe) and the second epitaxial layers are silicon. In embodiments wherein the first epitaxial layer includes SiGe and the second epitaxial layers includes silicon, the silicon oxidation rate is less than the SiGe oxidation rate.

In some embodiments, operation S1010 includes masking the epitaxial stack and patterning the epitaxial stack to form semiconductor fins 200, such as a dry etch (e.g., reactive ion etching), a wet etch, and/or other suitable process. Further, a portion the substrate 99 may be patterned such that a mesa portion of the substrate 99 forms a lower portion of the fins 200. In various embodiments, each fin 200 includes an upper portion of the interleaved epitaxial layers, and a bottom portion that is formed from the etched substrate 99. The fins 200 protrude upwardly in the Z-direction from the substrate 99, extend lengthwise in the X-direction, and are spaced apart in the Y-direction. The fins 200 may have a same width or different widths. In addition to forming fins 200, operation S1010 may include forming dummy fins 250.

Operation S1010 may also include forming shallow trench isolation (STI) features 240 in trenches adjacent to each fin 200. Also, operation S1010 may include forming sacrificial (dummy) gate structures. The sacrificial gate structures protrude upwardly in the Z-direction from the substrate 99, extend lengthwise in the Y-direction, and are spaced apart along the Y-direction.

The sacrificial gate structures are formed over portions of the fin 200 which are to be channel regions. The sacrificial gate structures may extend over a number of adjacent fins 200. The sacrificial gate structures lie directly over and define the channel regions of the semiconductor devices to be formed. Each of the sacrificial gate structures includes a sacrificial gate dielectric and a sacrificial gate electrode over the sacrificial gate dielectric. The sacrificial gate structures may be formed by first blanket depositing a sacrificial gate dielectric layer over the fins 200. A sacrificial gate electrode layer is then blanket deposited on the sacrificial gate dielectric layer and over the fins 200. The sacrificial gate dielectric layer includes silicon oxide, silicon nitride, or a combination thereof. The sacrificial gate electrode layer includes silicon such as polycrystalline silicon or amorphous silicon. The sacrificial gate dielectric layer and the sacrificial gate electrode layer may be deposited using CVD, including LPCVD and PECVD, PVD, ALD, or other suitable process. These layers are then masked and patterned into the sacrificial gate structures. After forming the sacrificial gate structures, each fin 200 is partially uncovered or exposed on opposite sides of the sacrificial gate structures, thereby defining source/drain (S/D) regions. In this disclosure, “source/drain region(s)” or “source/drain feature(s)” may refer to a source or a drain, individually or collectively dependent upon the context.

Operation S1010 may further include forming sidewall spacers on sidewalls of the sacrificial gate structures and sidewalls of the fins 200 by depositing spacer materials, followed by an etching. The sidewall spacers may include spacer material such as silicon oxide, silicon nitride, silicon carbide, silicon oxynitride, SiCN films, silicon oxycarbide, SiOCN films, and/or combinations thereof. In some embodiments, each of the spacers may include multiple layers, such as a liner layer and a main spacer layer on the liner layer. By way of example, the sidewall spacers may be formed by depositing spacer material including a liner material layer and a dielectric material layer over the sacrificial gate structure using processes such as a subatmospheric CVD (SACVD) process, a flowable CVD process, an ALD process, a PVD process, or other suitable process respectively.

Operation S1010 may include etching-back (e.g., anisotropically) to expose, and remove, portions of the fins 200 adjacent to and not covered by the sacrificial gate structure (e.g., source/drain regions). In some embodiments, the etching-back process may include a wet etch process, a dry etch process, a multiple-step etch process, and/or a combination thereof.

Operations S1010 may further include forming inner spacers by laterally etching the first epitaxial layers. In an exemplary embodiment, an SiGe etchback process is performed to laterally recess the first epitaxial layers. As a result, pockets are formed. Then, a material for forming the inner spacers is deposited. For example, the inner spacers may be formed from silicon oxides, silicon nitrides, silicon carbides, silicon carbide nitride, silicon oxide carbide, silicon carbide oxynitride, and/or other suitable dielectric materials. The inner spacers may be formed by ALD or any other suitable method. After depositing the material forming the inner spacers, the material may be trimmed from the sidewalls of second epitaxial layers.

Operation S1010 further includes forming source/drain features 650. In exemplary embodiments, the source/drain features 650 are formed by epitaxial growth. In exemplary embodiments, the source/drain features 650 are strained source/drain features 650. In certain embodiments, the source/drain features 650 may include an n-type epitaxial material source/drain features and a p-type epitaxial material source/drain features. The epitaxial material may include one or more layers of Si, SiP, SiC and SiCP for an n-channel FET or Si, SiGe, Ge for a p-channel FET. For the P-channel FET, boron (B) may also be contained in the source/drain. The source/drain epitaxial layers may be formed by an epitaxial growth method using CVD, ALD, or molecular beam epitaxy (MBE).

Operation S1010 may further include forming dielectric layers 660 over the source/drain features 650. Specifically, a dielectric liner may be formed over source/drain features 650 and along the sides of the spacers (not shown in the Figures). Further, a dielectric material may be formed over the liner over the source/drain features 650. In exemplary embodiments, the dielectric material is a first interlayer dielectric layer (ILD). The dielectric material may be silicon oxide or other suitable dielectric material. In certain embodiments, the ILD dielectric is the same material as the sidewall spacers. In certain embodiments, the dielectric liner is silicon nitride or another suitable material. The dielectric liner and material form the ILD dielectric layers 660. Further, operation S1010 may form dielectric caps 670 over the ILD dielectric 660 layers. For example, the dielectric caps 670 may be formed from silicon nitride and may protect the ILD dielectric layers 660 during later processing.

Operation S1010 may further include performing a replacement gate process including opening and removing the sacrificial gate structures. Specifically, a chemical mechanical planarization (CMP) process may be performed to remove overlying layers and to uncover the sacrificial gate structures. Then, the sacrificial gate structures are removed to form gate cavities bounded by sidewall spacers and located between ILD dielectric 660.

In operation S1010, the interposer first epitaxial layers may be removed. As a result, gaps are formed between the second epitaxial layers. In this manner, the second epitaxial layers are formed as vertically-spaced apart semiconductor nanosheets.

The replacement gate process is then completed by forming gates 300 in the gate cavities. In certain embodiments, the replacement metal gate process includes forming a gate dielectric layer in the gate cavities and in the gaps under the nanosheets, and forming a gate electrode material over the gate dielectric layer to fill the gate cavities and fill the gaps. An exemplary gate dielectric layer is deposited conformally. The gate dielectric may be formed on the semiconductor nanosheets, and the gate electrode material may be formed on the gate dielectric layer. Thus, each semiconductor nanosheet is wrapped in gate dielectric and surrounded by gate electrode material. In some embodiments, Si-based interfacial layers, such as silicon oxide or hafnium silicate, will be formed between semiconductor nanosheet and gate dielectrics. In accordance with some embodiments, the gate dielectric layer is formed from silicon oxide, silicon nitride, or multilayers thereof. In some embodiments, the gate dielectric layer is a high-k dielectric material, and in these embodiments, the gate dielectric layer may have a k value greater than about 7.0, and may include a metal oxide or a silicate of Hf, Al, Zr, La, Mg, Ba, Ti, Pb, and combinations thereof. The formation methods of the gate dielectric layer may include Molecular-Beam Deposition (MBD), ALD, PECVD, and the like.

The gate electrode material is deposited over the gate dielectric layer and fills the remaining portion of the gate cavity. The gate electrode material may be a metal-containing material such as TIN, TaN, TaC, Co, Ru, Al, combinations thereof, or multi-layers thereof. For example, any number of work function tuning layers may be deposited.

The replacement gate process includes removing excess portions of the gate dielectric layer and the gate electrode material located over the top surface of the ILD 660. For example, a planarization process, such as a CMP process, may be performed to remove the excess portions of the gate dielectric layer and the gate electrode material. The remaining portions of material of the gate dielectric layer and the gate electrode material thus form the replacement metal gate structure 300 of the resulting device 100. The gate dielectric layer and gate electrode material may be collectively referred to as a “gate,” a “gate stack,” or a “gate structure.” Each gate structure 300 may extend along sidewalls of a channel region of the fin structures 200.

Operation S1010 may further include forming a gate capping layer 350 over the gates 300. The gate capping layer 350 may be formed by initially depositing a dielectric material over the gates. In some embodiments, the gate capping layer 350 is formed using a dielectric material such as amorphous silicon, silicon nitride (SiN), oxide (OX), silicon oxynitride (SiON), silicon oxycarbonitride (SiOCN), silicon carbonitride (SiCN), or the like. The gate capping layer 350 may be formed using a suitable deposition process such as chemical vapor deposition (CVD), atomic layer deposition (ALD), physical vapor deposition (PVD), combinations of these, or the like. However, any suitable materials and deposition processes may be utilized. After being deposited, the gate capping layer 350 may be planarized using a planarization process such as a chemical mechanical polishing process.

Operation S1010 may include forming openings 390 in the gates 300, in accordance with some embodiments. After the gate capping layer 350 has been planarized, a mask may be deposited and patterned to expose the underlying materials including the gate capping layer 350 and gates 300 in desired locations where dielectric structures 400 are to be formed. For example, the dummy fins 250 may be aligned with the openings 390 as shown.

After mask patterning, the underlying materials are etched to form the openings 390. In the etching process, the materials of the gate capping layer 350 and the gates 300 are etched using an anisotropic etching process. The openings 390 may cut through one or more gates 300. According to some embodiments, two of the openings 390 are formed to cut through two adjacent gates 300 and are located on opposite sides of one or more of the fins 200.

Operation S1010 may further include forming dielectric structures 400, such as pillars 400, in the openings 390 in accordance with some embodiments. After the openings 901 have been formed, the dielectric pillars 400 are formed by initially depositing a dielectric material to fill and overfill the openings 390. In accordance with some embodiments, the dielectric material is formed using any dielectric material and deposition process suitable for forming the gate capping layer 350. In some embodiments, the dielectric material is the same as the dielectric material used to form the gate capping layer 350, although the dielectric materials may be different. For example, dielectric structures 400 may be formed using silicon nitride (SiN) in a deposition process such as Atomic Layer Deposition (ALD). However, any suitable dielectric materials and deposition processes may be used. According to some embodiments, the dielectric pillars 400.

As shown in FIG. 5, the dielectric pillars 400 extend into the dummy fins 250 and divide the gates 300, which are relatively long, into a plurality of gate segments 310 which are relatively short. The dielectric pillars 400 may be used to isolate the gate segments 310 from one another. For example, a selected gate segment 311 is separated from adjacent gate segments 312 by first dielectric pillar 401 and by second dielectric pillar 402. Likewise, the gate capping layer 350 is separated into segments 351 and 352 by pillars 400. Excess dielectric material 499 of the dielectric pillars 400 outside of the openings 390 may be retained and used as a masking layer during later etching.

Thus, as shown in FIG. 3-5, operation S1010 forms a structure 100 including a substrate 99, fins 200 overlying the substrate 99, a gate segment 311 overlying the fins 200 and extending in the Y-direction from a first end 321 to a second end 322, a dielectric layer segment 351 overlying the gate segment 311 and contacting the gate segment 311 at an interface height H1 over the substrate 99 defining a horizontal gate top plane, a first vertically-extending dielectric structure 401 having a first inner surface or sidewall 421 abutting the first end 321 of the gate segment 311, and a second vertically-extending dielectric structure 402 having a second inner surface or sidewall 422 abutting the second end 322 of the gate segment 311. As shown, the inner surfaces 421 and 422 are inclined toward or parallel to one another from a bottom end 423 of each dielectric structure 400 to a top end 424 of each dielectric structure 400.

As shown, a source/drain feature 650 is spaced from a gate segment 310 in the X-direction, an interlayer dielectric (ILD) structure 660 is located over the source/drain feature 650, and a cap 670 is located over the ILD structure 660. As shown, ILD structure 660 may be formed with sidewall liners 665 that are located along the sides of each ILD structures 660. Further, while not illustrated, the liner 665 may be located over the top surface of the source/drain features 650.

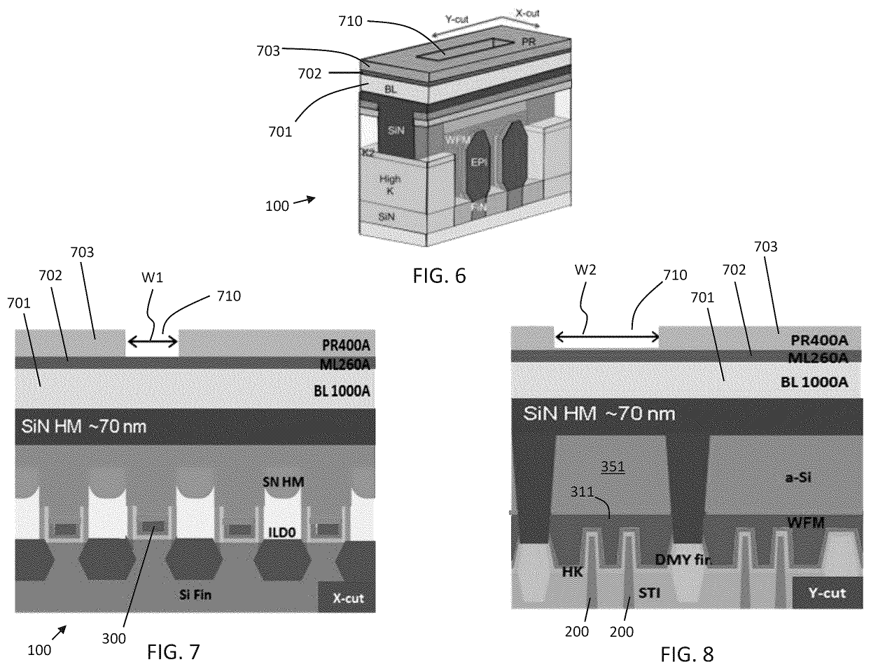

As shown in FIG. 31, method 1000 includes, at operation S1020, performing an etch process to remove the dielectric layer segment 351. FIGS. 6-8 illustrate an initial structure 100 during operation S1020. FIG. 6 is a perspective view of the semiconductor structure 100, FIG. 7 is an X-cut cross-sectional view along a fin 200, and FIG. 8 is a Y-cut cross-sectional view along a gate 300.

Cross-referencing FIGS. 6-8, operation S1020 may include forming a carbon based bottom layer 701, an oxide based middle layer 702, and an extreme ultraviolet (EUV) photo resist top layer 703 over the structure 100 of FIGS. 3-5. The etch process may include performing an extreme ultraviolet lithography (EUV) photo resist exposure technique to pattern the photo resist top layer 703 to form an opening 710. As shown, the opening 710 has a width W1 in the X-direction, and a width W2 in the Y-direction. Widths W1 and W2 may be selected to remove a single gate segment 351 from a single gate 300.

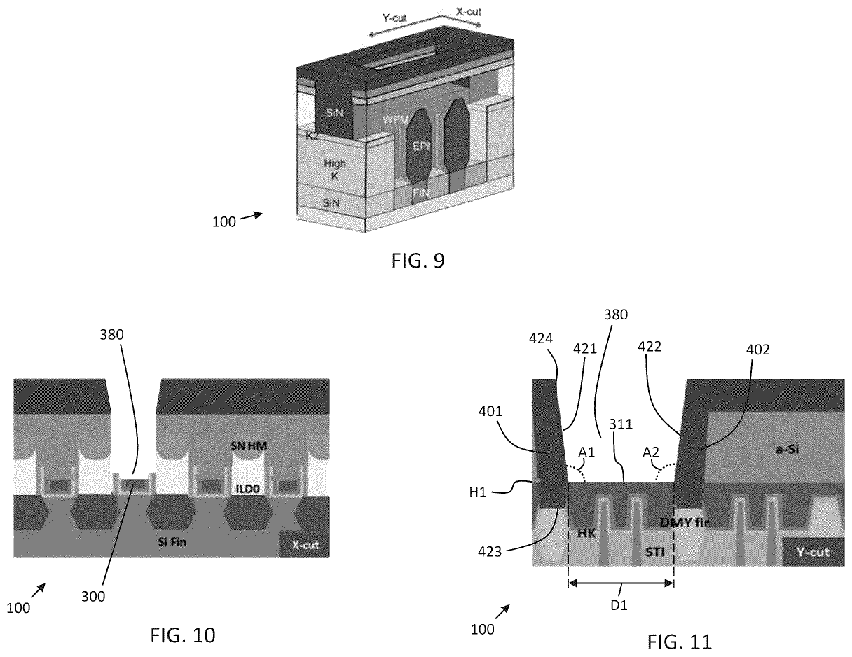

Operation S1020 further includes performing an etch process through the opening 710 to remove the dielectric layer segment 351, as shown in FIGS. 9-11. FIG. 9 is a perspective view of the semiconductor structure 100, FIG. 10 is an X-cut cross-sectional view along a fin 200, and FIG. 11 is a Y-cut cross-sectional view along a gate 300.

As shown in FIGS. 9-11, the etch process removes all of dielectric layer segment 351 and lands on gate segment 311. As a result, an opening 380 is formed.

In certain embodiments, the etch process etches the inner surfaces 421 and 422 of the vertically-extending dielectric structures 401 and 402 such that a minimum distance D1 between the vertically-extending dielectric structures 401 and 402 in the Y-direction is established at the interface height H1. Specifically, at the bottom ends 423, the dielectric structures 401 and 402 are distanced from one another, in the Y-direction, by a distance greater than minimum distance D1. The inner surfaces 421 and 422 of the dielectric structures 401 and 402 converge toward one another as the dielectric structures 401 and 402 extend vertically upward to the interface height H1. Then, as the dielectric structures 401 and 402 extend vertically upward from the interface height HI toward upper ends 424, the inner surfaces 421 and 422 of the dielectric structures 401 and 402 either move vertically upward or diverge away from one another. As a result, the distance between the inner surfaces 421 and 422 in the Y-direction at the upper ends 424 is equal to or greater than minimum distance D1.

As shown, inner sidewall 421 forms an internal angle A1 with the horizontal gate top plane at the interface height H1 and inner sidewall 422 forms an internal angle A2 with the horizontal gate top plane at the interface height H1. In certain embodiments, each internal angle A1 and A2 is independently at least 90 degrees.

In certain embodiments, each internal angle A1 and A2 is 90 degrees and the inner surfaces 421 and 422 are vertical as the dielectric structures 401 and 402 extend upward from the interface height H1. In other embodiments, at least one of angles A1 and A2 is greater than 90 degrees and the distance between the inner surfaces 421 and 422 of the dielectric structures 401 and 402 increases as the dielectric structures 401 and 402 extend upward from the interface height H1. In certain embodiments, each of angles A1 and A2 is greater than 90 degrees the inner surfaces 421 and 422 diverge away from one another as the dielectric structures 401 and 402 extend upward from the interface height H1.

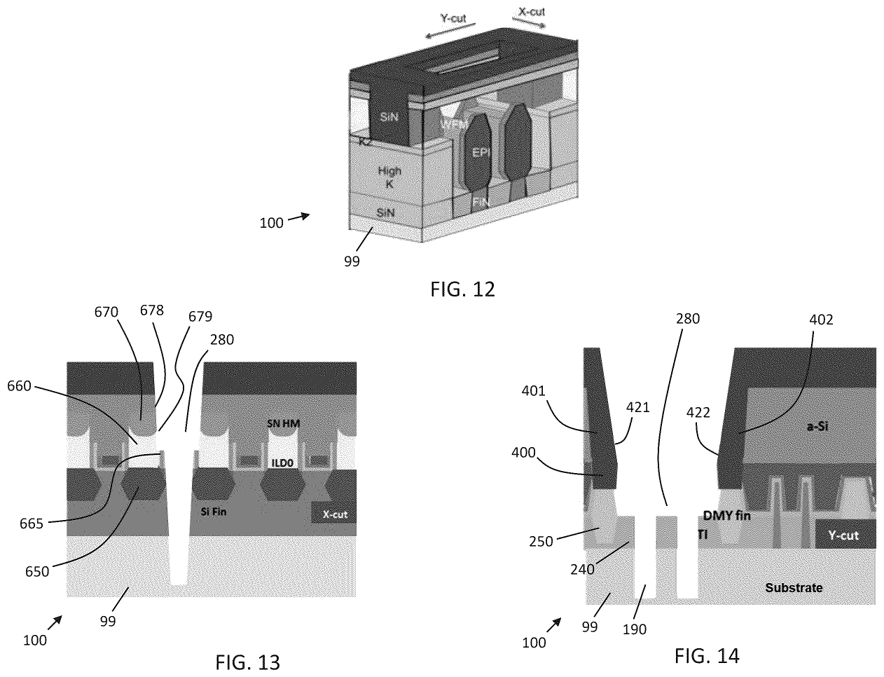

Referring to FIG. 31, method 1000 may continue at operation S1030 with removing the gate segment 311 and the fins 200 located below the gate segment 311 to form a cavity 280, as shown in FIGS. 12-14. FIG. 12 is a perspective view of the semiconductor structure 100, FIG. 13 is an X-cut cross-sectional view along a fin 200, and FIG. 14 is a Y-cut cross-sectional view along a gate 300.

As shown in FIGS. 12-14, removing the gate segment 311 forms cavity 280 and includes selectively removing the gate segment 311, including the gate material and gate dielectric. The gate segment 311 may be removed by a dry or wet etch. In certain embodiments, the process may remove all of the gate segment 311 between the dielectric structures 401 and 402 and over the STI 240. Further, the etch process may remove the nanostructures, etch the sidewall spacers, and recess the selected fins 200 into the substrate 99 to form cavity projections 190 extending downward from cavity 280 through the STI region 240 and into the substrate 99.

As a result, the cavity 280 is bounded by or defined by the substrate 99, STI 240, dummy fins 250 and dielectric structures 400. In certain embodiments, the etch process is a plasma etch and may be followed by a wet clean process.

While FIG. 13 illustrates that all of the gate segment 311 is removed, in certain embodiments, the etch process removes only substantially all of the gate segment 311. For example, a small remaining portion of the gate segment 311 may be present at a location 679 on the sidewall 678 below the portion of the sidewall 678 formed by cap 670, as indicated in FIG. 13. If present, the remaining portion of the gate segment 311 has a lateral thickness, in the X-direction of less than 3 nanometers (nm), such as less than 2.5, less than 2, less than 1.5, or less than 1 nm.

Further, while FIG. 13 illustrates that the sidewall liner 665 is not present at the location 679 on the sidewall 678 below the portion of the sidewall 678 formed by cap 670, in certain embodiments a small remaining portion of the sidewall liner 665 may be present at location 679. If present, the remaining portion of the sidewall liner 665 at location 679 has a lateral thickness, in the X-direction of less than 3 nanometers (nm), such as less than 2.5, less than 2, less than 1.5, or less than 1 nm.

In certain embodiments, the sidewall liner 665 remains intact and extends upward from the source/drain feature to the cap 670 such that no portion of sidewall 678 of opening 280 is formed by ILD structure 660. In other words, the sidewall liner 665 separates the ILD structure 660 from the opening 280.

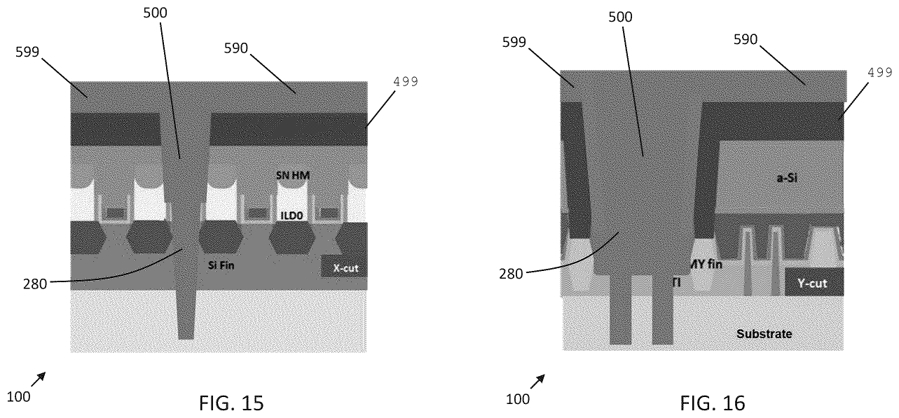

As shown in FIG. 31, method 1000 may continue at operation S1040 with forming an insulation feature 500 in the cavity 280, as shown in FIGS. 15 and 16. FIG. 15 is an X-cut cross-sectional view along a fin 200, and FIG. 16 is a Y-cut cross-sectional view along a gate 300.

As shown in FIGS. 15 and 16, forming the insulation feature 500 in the cavity 280 may include depositing an insulation material 590 in the cavity 280. The insulation material 590 may include a liner layer that lines the cavity 280 and a fill material. In certain embodiments, the insulation material 590 may include a liner of silicon oxide, oxynitride, a dielectric material having a dielectric constant (k) lower than silicon oxide (therefore referred to as low-k dielectric material layer), and/or other suitable dielectric material layer. In certain embodiments, the insulation material 590 may include a fill material including silicon nitride, oxynitride, and/or other suitable dielectric material layer. In certain embodiments, the fill material may be deposited with a refill process. In one example, the dielectric material may be deposited by chemical vapor deposition (CVD), atomic layer deposition (ALD), spin-on coating, or other suitable techniques. As shown, the dielectric material 590 may be first formed as a blanket layer and may form an overburden portion 599.

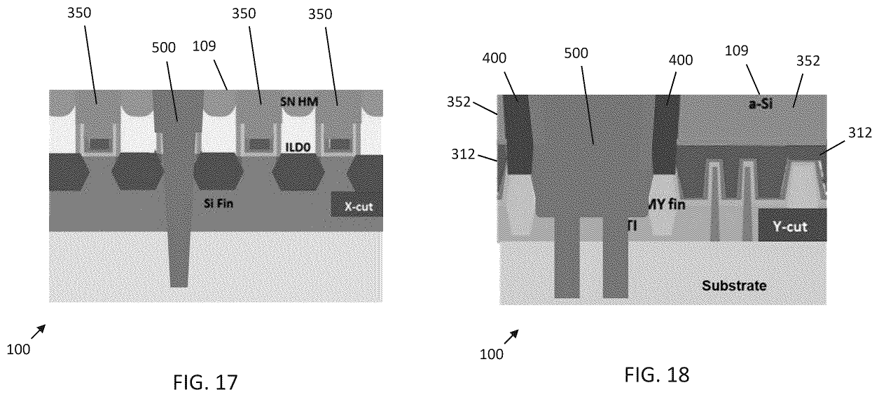

At operation S1040, forming the insulation feature 500 may further include performing a planarization process to remove the overburden portion 599 of the insulation material 590, as shown in FIGS. 17 and 18. FIG. 17 is an X-cut cross-sectional view along a fin 200, and FIG. 18 is a Y-cut cross-sectional view along a gate 300.

As shown in FIGS. 17 and 18, the planarization process to remove the overburden portion 599 of the insulation material 590 may remove the excess material 499 from over the remaining dielectric layer segments 352 located over the remaining gate segments 312. As a result, as shown in FIG. 18, an uppermost surface 109 of the structure 100 is defined and is formed by the insulation feature 500, the dielectric structures 400, and the remaining dielectric layer segments 352. As shown, at the upper surface 109 no portion of the dielectric layer segment 351 (shown in FIG. 8) is present.

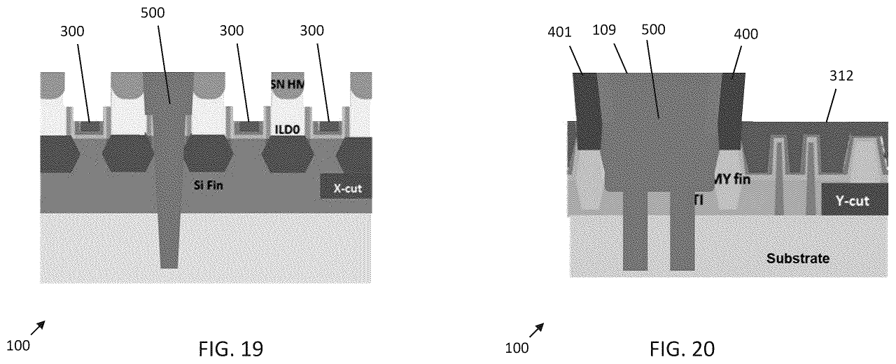

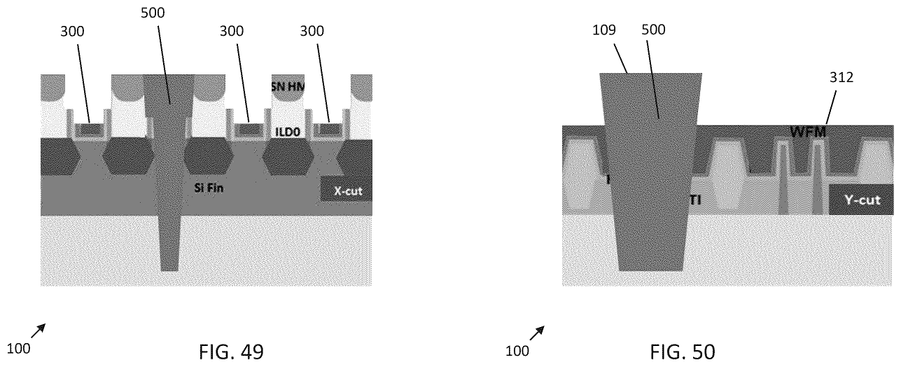

FIG. 31 illustrates that method 1000 may continue at operation S1050 with removing the remaining gate capping layer 350, including remaining dielectric layer segments 352. As a result, the remaining gates 300 and remaining gate segments 312 are uncovered. FIGS. 19 and 20 illustrate the structure 100 after operation S2050 is performed. FIG. 49 is an X-cut cross-sectional view along a fin 200, and FIG. 50 is a Y-cut cross-sectional view along a gate 300.

As shown in FIG. 20, after removing the remaining dielectric layer segments 352, the insulation feature 500 and the vertically-extending dielectric structures 400 remain in direct contact at the upper surface 109.

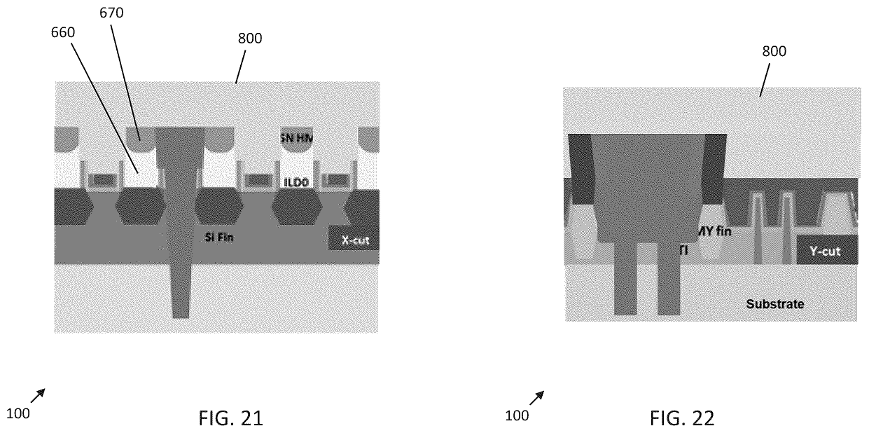

As shown in FIG. 31, method 1000 may further continue at operation S1060 with depositing an additional dielectric material 800 over the structure 100. FIGS. 21 and 22 illustrate this stage of fabrication. FIG. 21 is an X-cut cross-sectional view along a fin 200, and FIG. 22 is a Y-cut cross-sectional view along a gate 300.

In certain embodiments, the additional dielectric material 800 is silicon nitride.

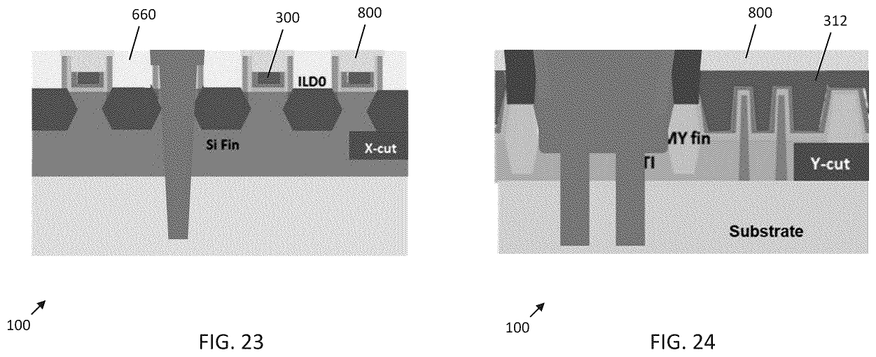

Method 1000 may continue at operation S1070 with planarizing the structure 100 as shown in FIGS. 31, 23, and 24. FIG. 23 is an X-cut cross-sectional view along a fin 200, and FIG. 24 is a Y-cut cross-sectional view along a gate 300. As shown, planarizing the structure 100 may include removing the caps 670 from over the ILD dielectric structures 660. As shown, a remaining portion of the additional dielectric material 800 remains over the remaining gates 300, including the remaining gate segment 312.

Method 1000 may continue at operation S1080 with forming conductive contacts in contact with the source/drain features 650 as shown in FIG. 31.

Various patterning approaches may be used to form conductive contacts, such as metal, on the source/drain features. For example, one approach may include depositing a silicon nitride based liner over the ILD dielectric structures 660 and depositing an additional interlayer dielectric (ILD) over the liner. Then, patterning and etching processes may be performed to remove non-covered regions of the additional ILD, silicon nitride based liner, and ILD dielectric structures 660 to reveal selected source/drain features 650. Deposition processes are then performed to form the conductive contacts. For example, a liner selected to avoid metal migration to neighboring dielectric material may be first deposited, and then a metal fill may be deposited to fill in the trenches. A CMP process may be then used to planarize the surface. Embodiments herein are not limited to any particular process for forming the conductive contacts.

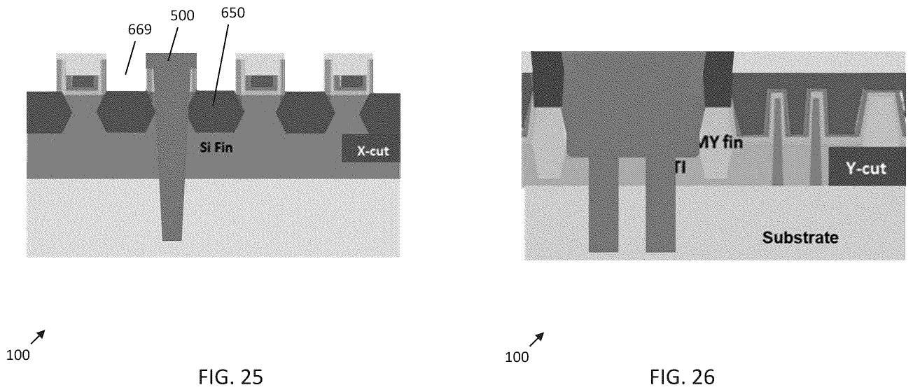

In the illustrated embodiment, an initial stage of operation S1080 is shown in FIGS. 25 and 26. FIG. 25 is an X-cut cross-sectional view along a fin 200, and FIG. 26 is a Y-cut cross-sectional view along a gate 300.

Operation S1080 may include removing the ILD dielectric structures 660, as shown in FIGS. 25 and 26. As shown, removing the ILD dielectric structures 660 forms cavities 669 over the source/drain features 650. The cavities 669 may abut the insulation feature 500, as shown in FIG. 25.

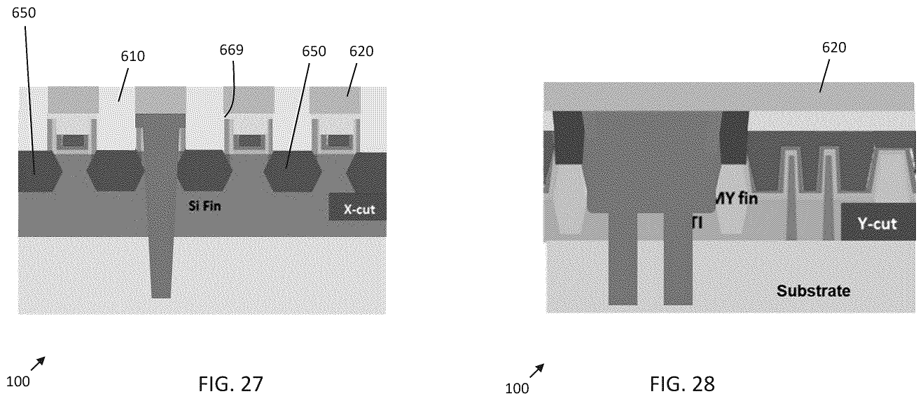

Operation S1080 may further include depositing a conductive material 610 over the structure 100 and in contact with the source/drain features 650, as shown in FIGS. 27 and 28. FIG. 27 is an X-cut cross-sectional view along a fin 200, and FIG. 28 is a Y-cut cross-sectional view along a gate 300. For example, a metal may be deposited.

As shown in FIGS. 27 and 28, operation S1080 may include forming and patterning a mask 620 over the structure 100. The mask 620 is patterned to uncover the source/drain features 650. Then, the conductive material 610 is deposited into contact with the source/drain features 650. For example, the conductive material 610 may fill the cavities 669.

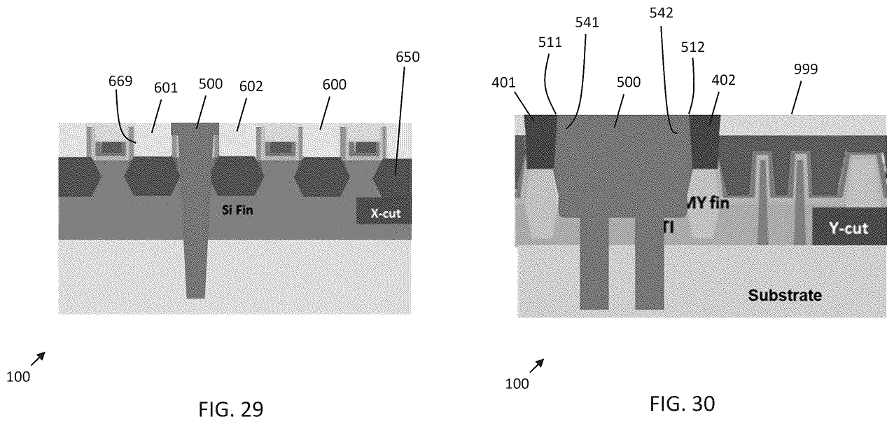

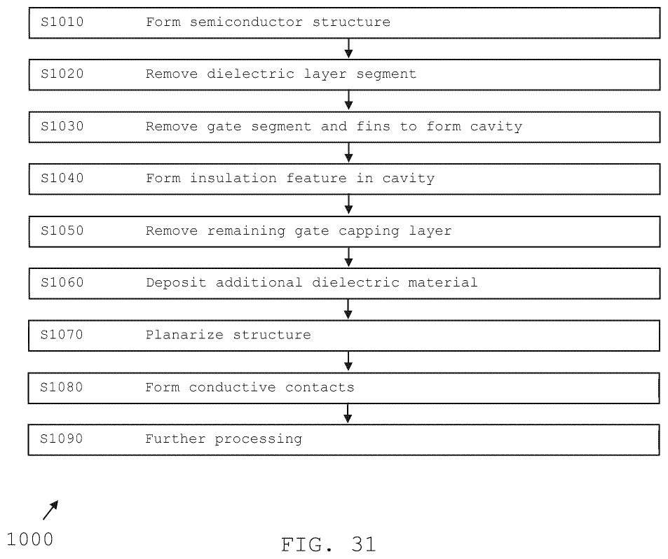

Operation S1080 may further include planarizing the structure 100 to define conductive contacts 600 in the cavities 669 over the source/drain features 650, as shown in FIGS. 29 and 30. FIG. 29 is an X-cut cross-sectional view along a fin 200, and FIG. 30 is a Y-cut cross-sectional view along a gate 300.

As shown in FIG. 31, method 1000 may continue with further processing at operation S1090. For example, various lithography, patterning, and passivation processes may be performed to form dielectric and metallization layers and to form a desired interconnect structure, such as in typical Back-end-of-line (BEOL) processing.

Cross-referencing FIGS. 2 and 29, the insulation feature 500 is located between two conductive contacts 600, i.e., first conductive contact 601 and second conductive contact 602. According to the processing provided herein, the first conductive contact 601 and second conductive contact 602 are completely isolated from one another. Further, the processing described herein prevents accidental connection of first conductive contact 601 and second conductive contact 602 around the insulation feature 500.

Cross-referencing FIGS. 2 and 30, at the upper surface 999 of structure 100, the insulation feature 500 extends in the Y-direction from first line end 511 to second line end 512. First line end 511 contacts the first vertically-extending dielectric structure 401, and second line end 512 contacts the second vertically-extending dielectric structure 402. Further, an upper portion 541 of the first line end 511 of the insulation feature 500 is surrounded by the first vertically-extending dielectric structure 401 and an upper portion 542 of the second line end 512 of the insulation feature 500 is surrounded by the second vertically-extending dielectric structure 402.

As described in FIGS. 2-31, the dielectric structures 400 are etched during removal of the gate segment 351. As a result, no portion of the gate segment 351 remains after the etching process due to protection by an overhang portion of the dielectric structures 400. A process that does not etch the dielectric structures 400 may not be able to remove all of the gate segment 351, as end portions of the gate segment 351 adjacent to the dielectric structures 400 may be protected from the etchant by the overlying slanted surfaces of the dielectric structures 400. Herein, overhang portions of the dielectric structures 400 are removed. As used herein, an overhang portion has an upper width that is greater than a lower width, such that a vertical anisotropic etching process is blocked by the upper width.

As described herein, no portion of the gate segment 351 remains lying directly under, and protected by, a portion of the dielectric structures 400. Rather, the dielectric structures 400 are etched such that inner surfaces 421 and 422 are either vertical or angled away from one another.

While FIGS. 2-31 present one embodiment for reducing or eliminating leaks from a source/drain contact 601 to an adjacent source/drain contact 602 around an insulation feature 500, another embodiment is provided.

FIG. 32 illustrates a top-down schematic layout view of a portion 100″ of a semiconductor structure 100, such as the structure of FIG. 1, according to some embodiments. In certain embodiments, portion 100″ may be located at a different location on a same structure 100 as portion 100′.

In FIG. 32, the schematic of the portion 100″ of structure 100 illustrates an insulation feature 500 extending in the Y-direction from a first line end 511 to a second line end 512. In certain embodiments, each line end 511 and 512 extends in the X-direction. As shown, the insulation feature 500 has a first sidewall 521 and a second sidewall 522 that each extend in the Y-direction. In FIG. 32, the insulation feature 500 does not abut or otherwise contact a dielectric structure 400 in this portion 100″ of the structure 100.

The insulation feature 500 is located between a first gate 301 and a second gate 302. In FIG. 32, the gates 301 and 302 do not abut or otherwise contact a dielectric structure 400 in this portion 100″ of the structure 100.

As further shown, source/drain contacts 600 are formed laterally adjacent to the insulation feature 500. Specifically, a first source/drain contact 601 is located between the first gate 301 and the insulation feature 500 and a second source/drain contact 601 is located between the second gate 302 and the insulation feature 500.

Each source/drain contact 600 extends in the Y-direction and terminates at a first contact end 611 and at a second contact end 612. Further, the first contact ends 611 define a first vertical plane 6110 perpendicular to a plane defined by the X and Y axes. As shown, the first vertical plane 6110 intersects the insulation feature 500. Likewise, the second contact ends 612 define a second vertical plane 6120 perpendicular to the plane defined by the X and Y axes. As shown, the second vertical plane 6120 intersects the insulation feature 500. More specifically, each vertical plane 6110 and 6120 intersects the sidewalls 521 and 522 of the insulation feature 500.

In certain embodiments, the first vertical plane 6110 is distanced in the Y-direction from the first line end 511 by a selected distance D1, and the second vertical plane 6120 is distanced in the Y-direction from the second line end 512 by a selected distance D2. Each selected distance D1 and D2 may independently be at least 0.1 nm, such as at least 0.2, at least 0.3, at least 0.4, at least 0.5, at least 0.6, at least 0.7, at least 0.8, at least 0.9, at least 1, at least 1.1, at least 1.2, at least 1.3, at least 1.4, at least 1.5, at least 1.6, at least 1.7, at least 1.8, at least 1.9, at least 2, at least 2.25, at least 2.5, at least 2.75, at least 3, at least 3.25, at least 3.5, at least 3.75, at least 4, at least 4.25, at least 4.5, at least 4.75, or at least 5 nm. Further, each selected distance D1 and D2 may independently be at most 0.1 nm, such as at most 0.2, at most 0.3, at most 0.4, at most 0.5, at most 0.6, at most 0.7, at most 0.8, at most 0.9, at most 1, at most 1.1, at most 1.2, at most 1.3, at most 1.4, at most 1.5, at most 1.6, at most 1.7, at most 1.8, at most 1.9, at most 2, at most 2.25, at most 2.5, at most 2.75, at most 3, at most 3.25, at most 3.5, at most 3.75, at most 4, at most 4.25, at most 4.5, at most 4.75, or at most 5 nm.

Generally, an increase in the distance D1 or D2 improves prevention of current leakage around the insulation feature 500. A minimum value of the distance D1 or D2 may depend on the technology node, generation, and/or application.

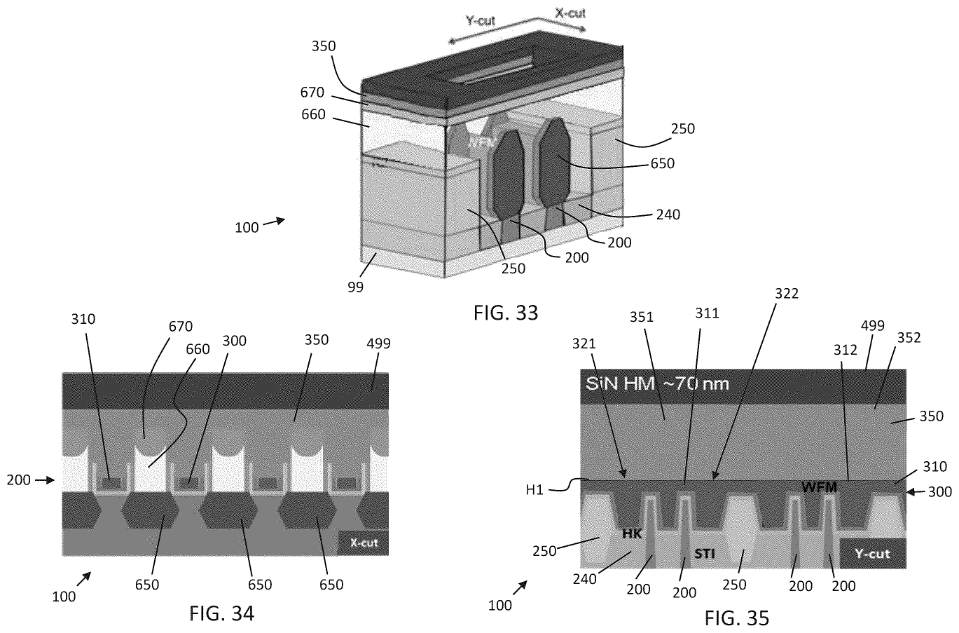

FIGS. 33-60 illustrate the portion 100″ of the semiconductor structure 100 at various stages of fabrication according to the method illustrated in FIG. 61.

As shown in FIG. 61, method 2000 may begin at operation S2010 with forming a semiconductor structure 100, as shown in FIGS. 33-35. FIG. 33 is a perspective view of the semiconductor structure 100 with certain features removed or transparent for clarity, FIG. 34 is an X-cut cross-sectional view along a fin 200, and FIG. 35 is a Y-cut cross-sectional view along a gate 300.

The structure 100 may be formed according to typical semiconductor processing as described in relation to operation S1010.

As shown in FIG. 35, no dielectric pillars 400 are located in the portion 100″ of the structure 100. As further shown, the excess dielectric material 499 of the dielectric pillars 400 outside of the openings 390 may be retained and used as a masking layer during later etching.

Thus, as shown in FIGS. 33-35, operation S2010 forms a structure 100 including a substrate 99, fins 200 overlying the substrate 99, a gate segment 311 overlying the fins 200 and extending in the Y-direction from a first end 321 to a second end 322 (in FIG. 35, the gate 300 is not interrupted at ends 321 and 322), and a dielectric layer segment 351 overlying the gate segment 311 and contacting the gate segment 311 at an interface height H1 over the substrate 99.

As shown, a source/drain feature 650 is spaced from a gate segment 310 in the X-direction, an interlayer dielectric (ILD) structure 660 is located over the source/drain feature 650, and a cap 670 is located over the ILD structure 660.

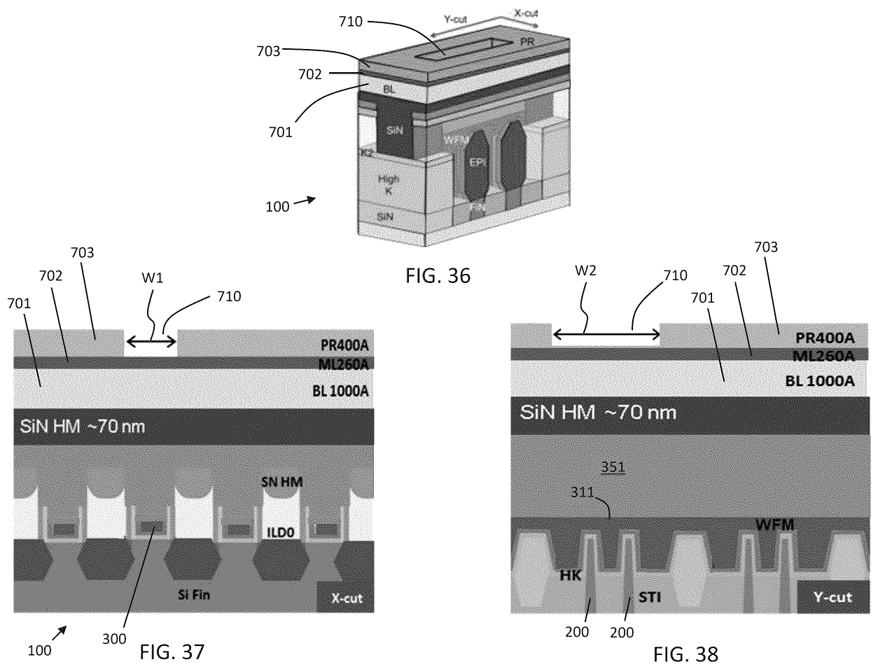

As shown in FIG. 61, method 2000 includes, at operation S2020, performing an etch process to remove the dielectric layer segment 351. FIGS. 36-38 illustrate an initial structure 100 during operation S2020. FIG. 36 is a perspective view of the semiconductor structure 100, FIG. 37 is an X-cut cross-sectional view along a fin 200, and FIG. 38 is a Y-cut cross-sectional view along a gate 300.

Cross-referencing FIGS. 36-38, operation S2020 may include forming a carbon based bottom layer 701, an oxide based middle layer 702, and an extreme ultraviolet (EUV) photo resist top layer 703 over the structure 100 of FIGS. 33-35. The etch process may include performing an extreme ultraviolet lithography (EUV) photo resist exposure technique to pattern the photo resist top layer 703 to form an opening 710. As shown, the opening 710 has a width W1 in the X-direction, and a width W2 in the Y-direction. Widths W1 and W2 may be selected to remove a single gate segment 351 from a single gate 300.

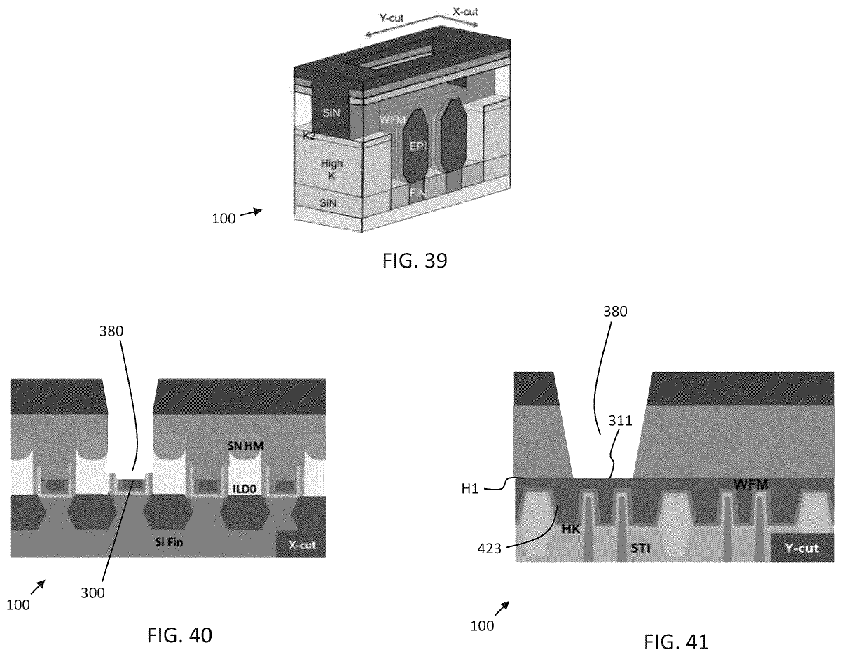

Operation S2020 further includes performing an etch process through the opening 710 to remove the dielectric layer segment 351, as shown in FIGS. 39-41. FIG. 39 is a perspective view of the semiconductor structure 100, FIG. 40 is an X-cut cross-sectional view along a fin 200, and FIG. 41 is a Y-cut cross-sectional view along a gate 300.

As shown in FIGS. 39-41, the etch process removes all of dielectric layer segment 351 and lands on gate segment 311. As a result, an opening 380 is formed.

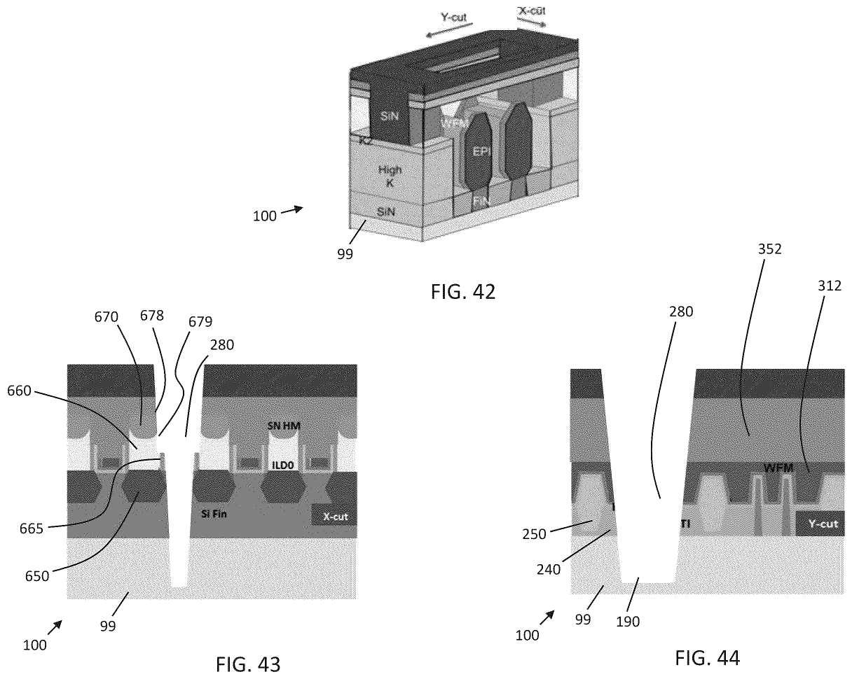

Referring to FIG. 61, method 2000 may continue at operation S2030 with removing the gate segment 311 and the fins 200 located below the gate segment 311 to form a cavity 280, as shown in FIGS. 42-44. FIG. 42 is a perspective view of the semiconductor structure 100, FIG. 43 is an X-cut cross-sectional view along a fin 200, and FIG. 44 is a Y-cut cross-sectional view along a gate 300.

As shown in FIGS. 42-44, removing the gate segment 311 forms cavity 280 and includes selectively removing the gate segment 311, including the gate material and gate dielectric. The gate segment 311 may be removed mainly by anisotropic plasma etch accompanying with wet clean processes, to avoid the damage of neighboring metal gate structure 312 (unlike method 1000, in method 2000 dielectric pillars are not present to protect the neighboring metal gate structure 312). In some embodiments, the anisotropic etch processes for removing the gate segment 311 may lead to substantial recessing of STI 240. In certain embodiments, the process may remove all of the gate segment 311 located under the removed dielectric layer segment 351 and over the STI 240. Further, the etch process may remove the nanostructures, etch the sidewall spacers, and recess the selected fins 200 into the substrate 99 to form cavity projections 190 extending downward from cavity 280 through the STI region 240 and into the substrate 99. In some embodiments, a notched etch profile will be obtained, due to the different etch rates of the STI 240, the channel materials, and the metal gate segment 311.

As a result, the cavity 280 is bounded by or defined by the substrate 99, STI 240, remaining gate segments 312, and remaining dielectric layer segments 352. In certain embodiments, the etch process is a plasma etch and may be followed by a wet clean process.

While FIG. 43 illustrates that all of the gate segment 311 is removed, in certain embodiments, the etch process removes only substantially all of the gate segment 311. For example, a small remaining portion of the gate segment 311 may be present at a location 679 on the sidewall 678 below the portion of the sidewall 678 formed by cap 670, as indicated in FIG. 43. If present, the remaining portion of the gate segment 311 has a lateral thickness, in the X-direction of less than 3 nanometers (nm), such as less than 2.5, less than 2, less than 1.5, or less than 1 nm.

Further, while FIG. 43 illustrates that the sidewall liner 665 is not present at the location 679 on the sidewall 678 below the portion of the sidewall 678 formed by cap 670, in certain embodiments a small remaining portion of the sidewall liner 665 may be present at location 679. If present, the remaining portion of the sidewall liner 665 at location 679 has a lateral thickness, in the X-direction of less than 3 nanometers (nm), such as less than 2.5, less than 2, less than 1.5, or less than 1 nm.

In certain embodiments, the sidewall liner 665 remains intact and extends upward from the source/drain feature to the cap 670 such that no portion of sidewall 678 of opening 280 is formed by ILD structure 660. In other words, the sidewall liner 665 separates the ILD structure 660 from the opening 280.

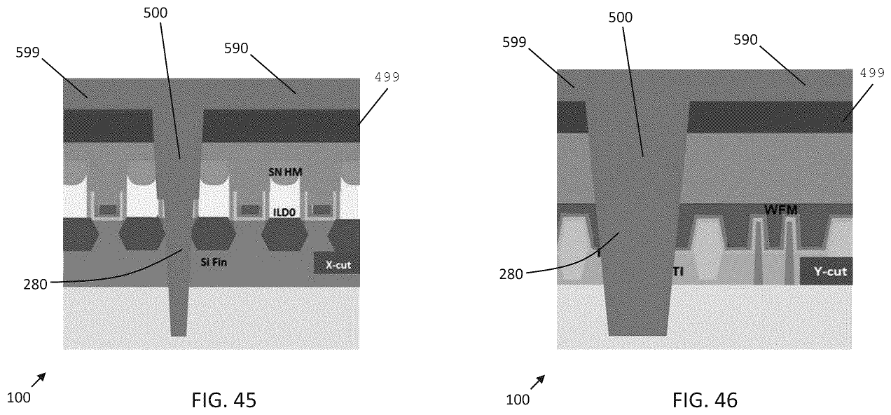

As shown in FIG. 61, method 2000 may continue at operation S2040 with forming an insulation feature 500 in the cavity 280, as shown in FIGS. 45 and 46. FIG. 45 is an X-cut cross-sectional view along a fin 200, and FIG. 46 is a Y-cut cross-sectional view along a gate 300.

As shown in FIGS. 45 and 46, forming the insulation feature 500 in the cavity 280 may include depositing an insulation material 590 in the cavity 280. The insulation material 590 may include a liner layer that lines the cavity 280 and a fill material. In certain embodiments, the insulation material 590 may include a liner of silicon oxide, oxynitride, a dielectric material having a dielectric constant (k) lower than silicon oxide (therefore referred to as low-k dielectric material layer), and/or other suitable dielectric material layer. In certain embodiments, the insulation material 590 may include a fill material including silicon nitride, oxynitride, and/or other suitable dielectric material layer. In certain embodiments, the fill material may be deposited with a refill process. In one example, the dielectric material may be deposited by chemical vapor deposition (CVD), atomic layer deposition (ALD), spin-on coating, or other suitable techniques. As shown, the dielectric material 590 may be first formed as a blanket layer and may form an overburden portion 599.

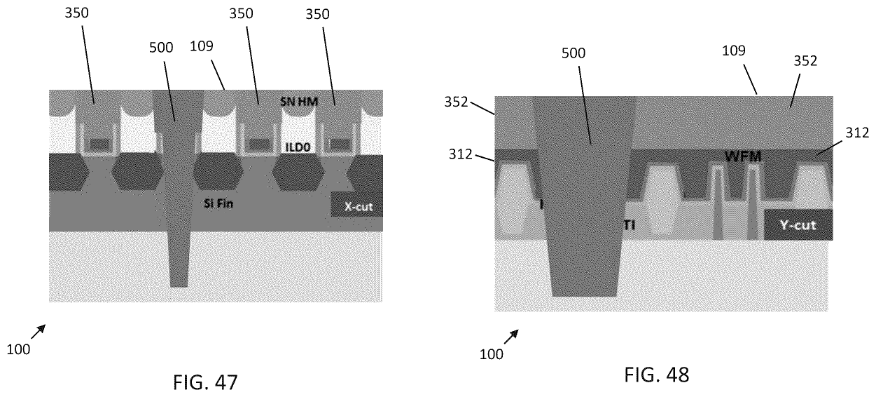

At operation S2040, forming the insulation feature 500 may further include performing a planarization process to remove the overburden portion 599 of the insulation material 590, as shown in FIGS. 47 and 48. FIG. 47 is an X-cut cross-sectional view along a fin 200, and FIG. 48 is a Y-cut cross-sectional view along a gate 300.

As shown in FIGS. 47 and 48, the planarization process to remove the overburden portion 599 of the insulation material 590 may remove the excess material 499 from over the remaining dielectric layer segments 352 located over the remaining gate segments 312. As a result, as shown in FIG. 48, an uppermost surface 109 of the structure 100 is defined and is formed by the insulation feature 500 and the remaining dielectric layer segments 352.

FIG. 61 illustrates that method 2000 may continue at operation S2050 with removing the remaining gate capping layer 350, including remaining dielectric layer segments 352. As a result, the remaining gates 300 and remaining gate segments 312 are uncovered. FIGS. 49 and 50 illustrate the structure 100 after operation S2050 is performed. FIG. 49 is an X-cut cross-sectional view along a fin 200, and FIG. 50 is a Y-cut cross-sectional view along a gate 300.

As shown in FIG. 50, after removing the remaining dielectric layer segments 352, the insulation feature 500 and the remaining gate segments 352 remain in direct contact.

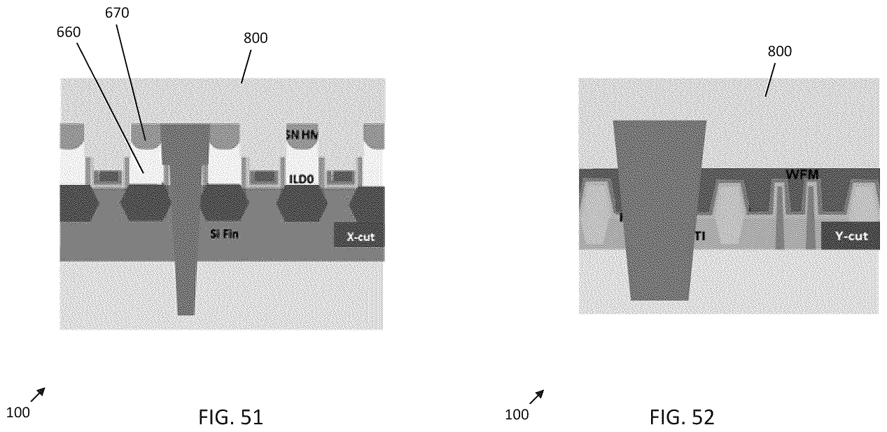

As shown in FIG. 61, method 2000 may further continue at operation S2060 with depositing an additional dielectric material 800 over the structure 100. FIGS. 51 and 52 illustrate this stage of fabrication. FIG. 51 is an X-cut cross-sectional view along a fin 200, and FIG. 52 is a Y-cut cross-sectional view along a gate 300.

In certain embodiments, the additional dielectric material 800 is silicon nitride.

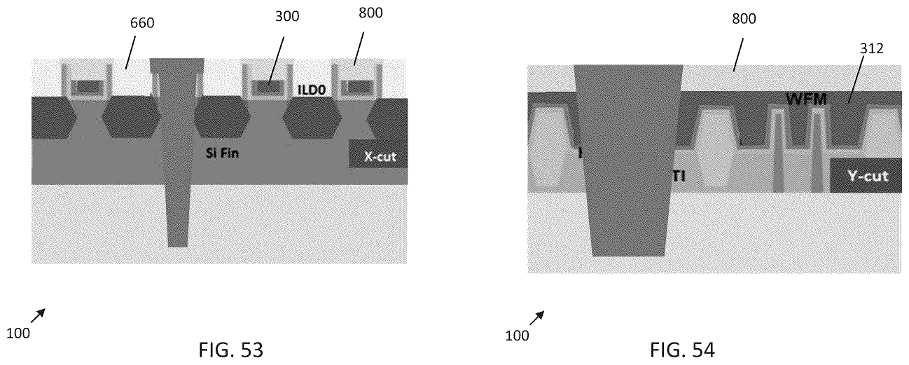

Method 2000 may continue at operation S2070 with planarizing the structure 100 as shown in FIGS. 61, 53, and 54. FIG. 53 is an X-cut cross-sectional view along a fin 200, and FIG. 54 is a Y-cut cross-sectional view along a gate 300. As shown, planarizing the structure 100 may include removing the caps 670 from over the ILD dielectric structures 660. As shown, a remaining portion of the additional dielectric material 800 remains over the remaining gates 300, including the remaining gate segment 312.

Method 2000 may continue at operation S2080 with forming conductive contacts in contact with the source/drain features 650.

Various patterning approaches may be used to form conductive contacts, such as metal, on the source/drain features. For example, one approach may include depositing a silicon nitride based liner over the ILD dielectric structures 660 and depositing an additional interlayer dielectric (ILD) over the liner. Then, patterning and etching processes may be performed to remove non-covered regions of the additional ILD, silicon nitride based liner, and ILD dielectric structures 660 to reveal selected source/drain features 650. Deposition processes are then performed to form the conductive contacts. For example, a liner selected to avoid metal migration to neighboring dielectric material may be first deposited, and then a metal fill may be deposited to fill in the trenches. A CMP process may be then used to planarize the surface. Embodiments herein are not limited to any particular process for forming the conductive contacts.

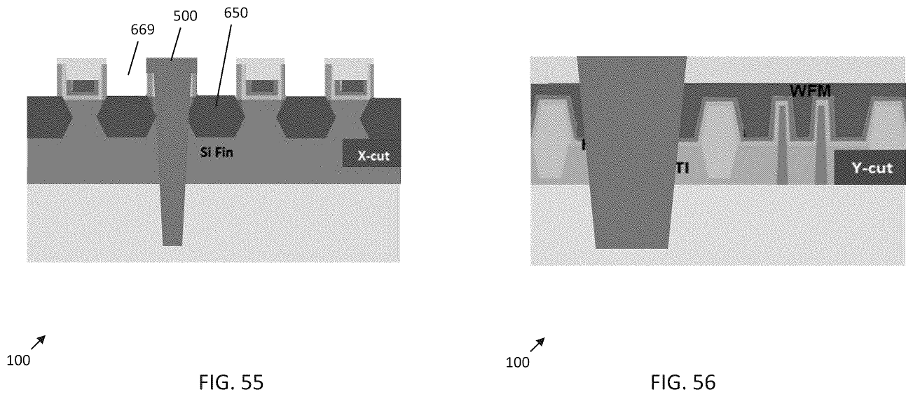

In the illustrated embodiment, an initial stage of operation S2080 is shown in FIGS. 55 and 56. FIG. 55 is an X-cut cross-sectional view along a fin 200, and FIG. 56 is a Y-cut cross-sectional view along a gate 300.

Operation S2080 may include removing the ILD dielectric structures 660, as shown in FIGS. 55 and 56. As shown, removing the ILD dielectric structures 660 forms cavities 669 over the source/drain features 650. The cavities 669 may abut the insulation feature 500, as shown in FIG. 55.

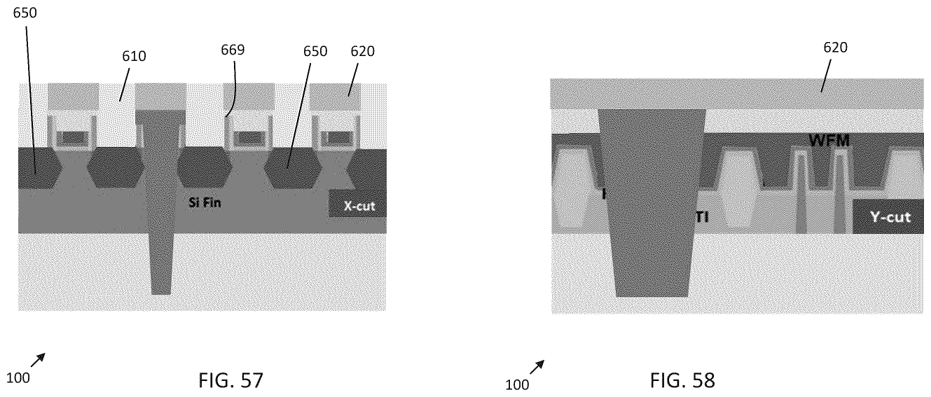

Operation S2080 may further include depositing a conductive material 610 over the structure 100 and in contact with the source/drain features 650, as shown in FIGS. 57 and 58. FIG. 57 is an X-cut cross-sectional view along a fin 200, and FIG. 58 is a Y-cut cross-sectional view along a gate 300. For example, a metal may be deposited.

As shown in FIGS. 57 and 58, operation S2080 may include forming and patterning a mask 620 over the structure 100. The mask 620 is patterned to uncover the source/drain features 650. Then, the conductive material 610 is deposited into contact with the source/drain features 650. For example, the conductive material 610 may fill the cavities 669.

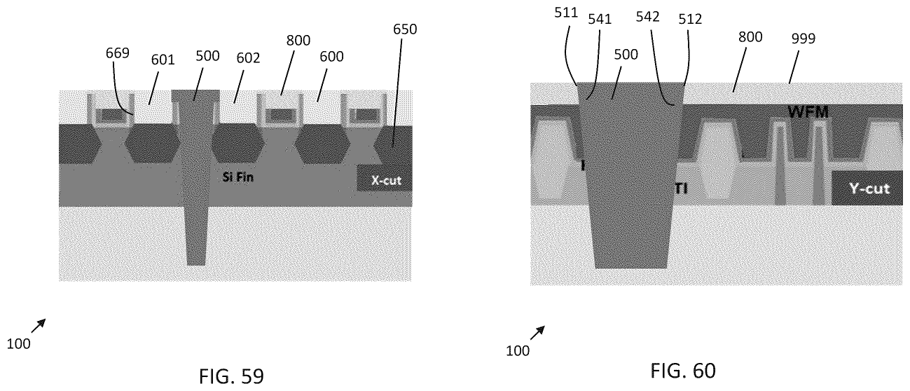

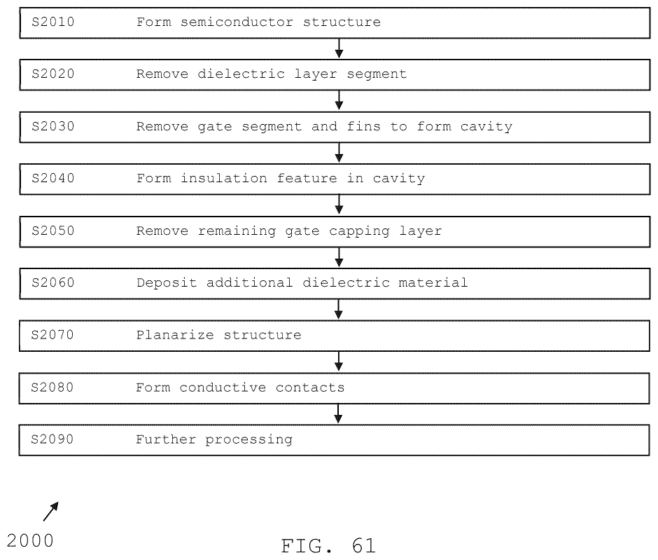

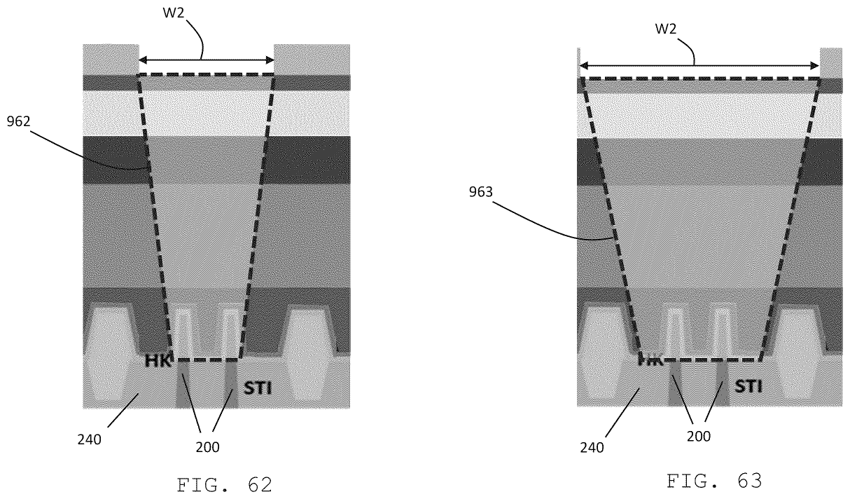

Operation S1080 may further include planarizing the structure 100 to define conductive contacts 600 in the cavities 669 over the source/drain features 650, as shown in FIGS. 59 and 60. FIG. 59 is an X-cut cross-sectional view along a fin 200, and FIG. 60 is a Y-cut cross-sectional view along a gate 300.

As shown in FIG. 61, method 2000 may continue with further processing at operation S1090. For example, various lithography, patterning, and passivation processes may be performed to form dielectric and metallization layers and to form a desired interconnect structure, such as in typical Back-end-of-line (BEOL) processing.

Cross-referencing FIGS. 32 and 59, the insulation feature 500 is located between two conductive contacts 600, i.e., first conductive contact 601 and second conductive contact 602. According to the processing provided herein, the first conductive contact 601 and second conductive contact 602 are completely isolated from one another. Further, the processing described herein prevents accidental connection of the first conductive contact 601 and second conductive contact 602 around the insulation feature 500.

Cross-referencing FIGS. 32 and 60, at the upper surface 999 of structure 100, the insulation feature 500 extends in the Y-direction from first line end 511 to second line end 512. First line end 511 contacts the dielectric material 800, and second line end 512 contacts the dielectric material 800. Further, an upper portion 541 of the first line end 511 of the insulation feature 500 is surrounded by the dielectric material 800 and an upper portion 542 of the second line end 512 of the insulation feature 500 is surrounded by the dielectric material 800.

As described in FIGS. 32-61, line ends 511 and 512 are distanced from source/drain contacts 601 and 602 to avoid leakage from source/drain contact 601 to source/drain contact 602 around the insulation feature 500.

FIG. 62 is a focused view of the fabrication stage of method 2000 at FIG. 38, with the material above STI 240 to be etched indicated in outline 962 in accordance with one embodiment. FIG. 62 is a Y-cut cross-sectional view along a gate 300.

FIG. 63 is a focused view of the fabrication stage of method 2000 at FIG. 38, with the material above STI 240 to be etched indicated in outline 963 in accordance with another embodiment. FIG. 63 is a Y-cut cross-sectional view along a gate 300.

Cross-referencing FIGS. 62 and 63, it may be seen that, due to the fact that method 2000 does not include forming the CMODE/CPODE insulation feature 500 in abutment with dielectric structures 400, method 2000 is not limited to using a minimum photo mask opening width W2 (in the Y-direction) that is restricted by the location of dielectric structures 400. Rather, the width W2 may be reduced to only remove the selected fins, as in FIG. 62. Larger widths W2 may also be used, such as in FIG. 63, as desired.

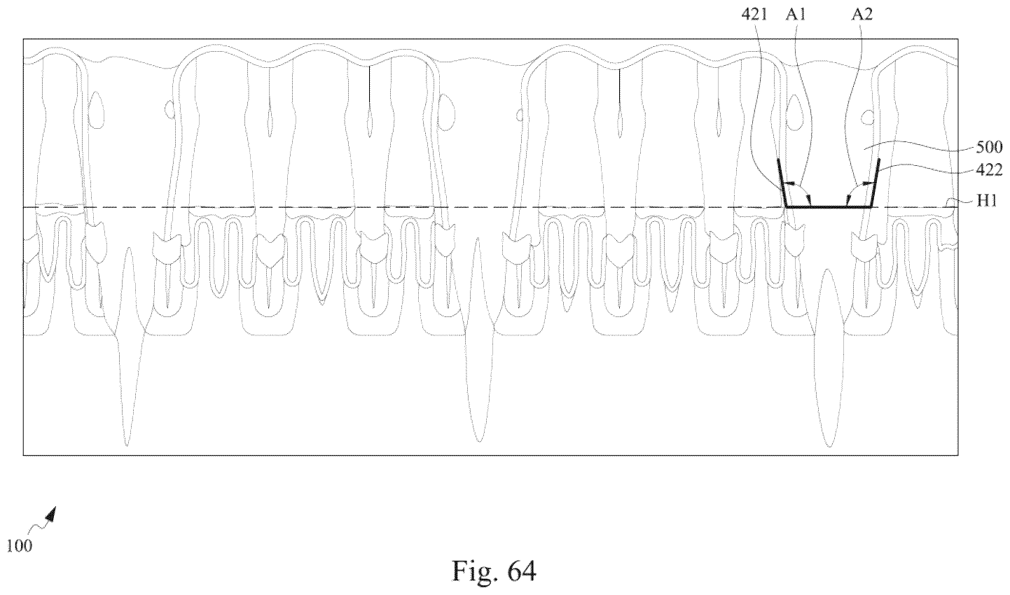

FIG. 64 is a transmission electron microscope (TEM) image of a portion 100′ of a semiconductor device 100, as formed according to method 1000. FIG. 64 illustrates the internal angles A1 and A2 of the inner sidewalls 421 and 422 at the gate top plane at height H1. TEM analysis may be used to determine the angles A1 and A2.

In certain embodiments, each of angle A1 and angle A2 is, independently, 90 degrees, or is greater than 90 degrees. For example, both or either angle may be at least 90.5, at least 91, at least 91.5, at least 92, at least 92.5, at least 93, at least 93.5, at least 94, at least 94.5, at least 95, at least 95.5, at least 96, at least 96.5, at least 97, at least 97.5, at least 98, at least 98.5, at least 99, at least 99.5, at least 100, or at least 100.5 degrees. Further, both or either angle may be at most 90.5, at most 91, at most 91.5, at most 92, at most 92.5, at most 93, at most 93.5, at most 94, at most 94.5, at most 95, at most 95.5, at most 96, at most 96.5, at most 97, at most 97.5, at most 98, at most 98.5, at most 99, at most 99.5, at most 100, or at most 100.5 degrees.

When angle A1 or angle A2 is at least 90 degrees, there can be no portion of the gate 300, i.e. no portion of selected gate segment 311, shadowed by or located directly under the dielectric structure 400. In other words, when angle A1 and A2 are at least 90 degrees, no portion of the selected gate segment 311 is hidden by the dielectric structure 400 during the directional etch process used to remove the selected gate segment 311. As a result, the selected gate segment 311 may be completely removed. Thus, the risk for current leakage is substantially reduced. For example, if a remnant portion of the selected gate segment 311 remains in the trench after the etch process for removing the selected gate segment 311, then the remnant portion will be removed during later processing and form an air gap. During subsequent processing, metal will fill the air gap-thereby creating a leakage pathway. Thus, maintaining angles A1 and A2 90 degrees or greater prevent formation of air gaps that lead to current leakage pathways.

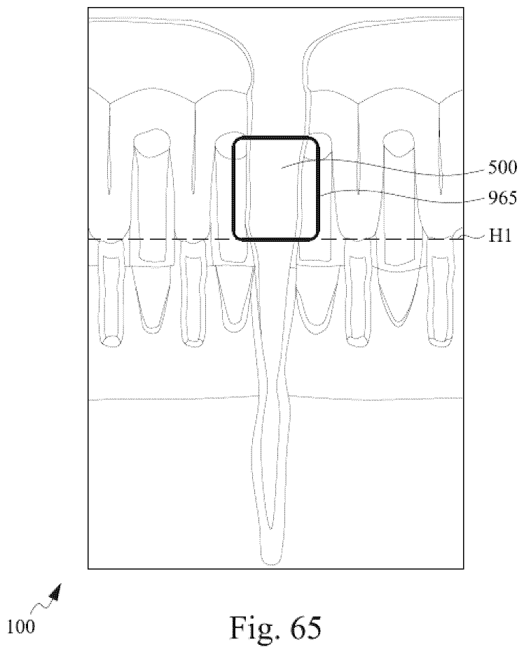

FIG. 65 is a transmission electron microscope (TEM) image of a portion 100′ of a semiconductor device 100, as formed according to method 1000. FIG. 65 identifies a region 965 at and above the gate top plane at height H1. In the region 965, the insulation feature 500 is located. In certain embodiments, no portion of the gate capping layer 350 remains in the region 965.

In one embodiment, a method includes forming a structure including a substrate, fins overlying the substrate, a gate segment overlying the fins and extending in a first lateral direction from a first end to a second end, a dielectric layer segment overlying the gate segment and contacting the gate segment at an interface height, a first vertically-extending dielectric structure having a first inner surface abutting the first end of the gate segment, and a second vertically-extending dielectric structure having a second inner surface abutting the second end of the gate segment, wherein the inner surfaces are inclined toward or parallel to one another from a bottom end to a top end; performing an etch process to remove the dielectric layer segment, wherein the etch process etches the inner surfaces of the vertically-extending dielectric structures such that a minimum distance between the vertically-extending dielectric structures is established at the interface height; removing the gate segment and the fins located below the gate segment to form a cavity; and forming an insulation feature in the cavity, wherein the insulation feature extends in the first lateral direction from a first line end to a second line end, wherein the first line end contacts the first vertically-extending dielectric structure, and wherein the second line end contacts the second vertically-extending dielectric structure.

In certain embodiments of the method, forming the insulation feature in the cavity includes depositing an insulation material in the cavity; and performing a planarization process to remove an overburden portion of the insulation material.

In certain embodiments of the method, the planarization process to remove an overburden portion of the insulation material forms an upper surface of the structure, and wherein at the upper surface no portion of the dielectric layer segment is present.

In certain embodiments of the method, a remaining gate segment is located adjacent to the insulation feature; a remaining dielectric layer segment is located over the remaining gate segment; the upper surface of the structure is formed by the insulation feature and the remaining dielectric layer segment; the method further includes removing the remaining dielectric layer segment; and after removing the remaining dielectric layer segment, the insulation feature and the vertically-extending dielectric structures remain in direct contact at the upper surface.

In certain embodiments of the method, after forming the structure, a source/drain feature is spaced from the gate segment in a second lateral direction perpendicular to the first lateral direction, an interlayer dielectric (ILD) structure is located over the source/drain feature, and a cap is located over the ILD structure; and the method further includes after removing the remaining dielectric layer segment, depositing an additional dielectric material over the structure; performing an additional planarization process to remove the cap, wherein a remaining portion of the additional dielectric material remains over the remaining gate segment; removing the ILD structure; and forming a conductive contact in contact with the source/drain feature.

In certain embodiments of the method, the etch process forms each inner surface at the interface height at an internal angle to a horizontal line, when each internal angle is at least 90 degrees.

In certain embodiments of the method, the insulation feature is formed with an upper portion; the upper portion has a belted shape with a lower end having a lower thickness in the first lateral direction, a middle at the interface height having a middle thickness in the first lateral direction, and an upper end having an upper thickness in the first lateral direction; and the middle thickness is less than the lower thickness and is less than the upper thickness.

In certain embodiments of the method, the insulation feature has an uppermost surface; the insulation feature has a first thickness in the first lateral direction at the interface height; the insulation feature has a second thickness in the first lateral direction at the uppermost surface; and the second thickness is greater than the first thickness.

In certain embodiments of the method, performing the etch process to remove the dielectric layer segment etches the inner surfaces of the vertically-extending dielectric structures such that the inner surfaces are vertical.

In another embodiment, a method includes forming a structure including a substrate, fins overlying the substrate and extending in a lateral X-direction, a gate structure overlying the fins and extending in a lateral Y-direction perpendicular to the lateral X-direction, a dielectric layer overlying the gate structure, and at least one vertically-extending dielectric structure cutting through the dielectric layer and the gate structure; performing an etch process to remove a selected portion of the dielectric layer to form an opening, wherein the opening does not contact the at least one vertically-extending dielectric structure; removing a portion of the gate structure located below the opening and the fins located below the opening to form a cavity; and forming an insulation feature in the cavity.

In certain embodiments of the method, the insulation feature is distanced from each at least one vertically-extending dielectric structure by a non-zero distance.

In certain embodiments of the method, forming the insulation feature in the cavity includes: depositing an insulation material in the cavity; and performing a planarization process to remove an overburden portion of the insulation material.

In certain embodiments of the method, an upper surface of the structure is formed by the insulation feature and a remaining portion of the dielectric layer; the method further includes removing the remaining portion of the dielectric layer; and after removing the remaining portion of the dielectric layer, upper portions of sidewalls of the insulation feature are uncovered.

In certain embodiments of the method, after forming the structure, a source/drain feature is spaced from the gate structure in the lateral X-direction, an interlayer dielectric (ILD) structure is located over the source/drain feature, and a cap is located over the ILD structure; and the method further includes: after removing the remaining portion of the dielectric layer, depositing an additional dielectric material over the structure; performing an additional planarization process to remove the cap, wherein a remaining portion of the additional dielectric material remains over a remaining portion of the gate structure; removing the ILD structure; and forming a conductive contact in contact with the source/drain feature.

In certain embodiments of the method, the insulation feature extends in the lateral Y-direction from a first line end to a second line end, wherein the first line end contacts a first portion of the additional dielectric material, and wherein the second line end contacts a second portion of the additional dielectric material.

In another embodiment, a semiconductor structure includes a first gate structure and a second gate structure distanced from one another in a lateral Y-direction, wherein each gate structure extends in a lateral X-direction perpendicular to the lateral Y-direction; an insulation feature distanced from the first gate structure and the second gate structure in the lateral Y-direction, wherein the insulation feature extends in the lateral X-direction from a first line end to a second line end; a first conductive contact located between the first gate structure and the insulation feature and a second conductive contact located between the second gate structure and the insulation feature; wherein: each conductive contact extends in the lateral Y-direction, terminates at a first contact end, and terminates at a second contact end; the first contact ends define a first vertical plane that intersects the insulation feature; and the second contact ends define a second vertical plane that intersects the insulation feature.

In certain embodiments, the semiconductor structure, further includes a first vertically-extending dielectric structure and a second vertically-extending dielectric structure, the first vertically-extending dielectric structure and the second vertically-extending dielectric structure extend in the lateral X-direction and are distanced from one another in the lateral Y-direction; an upper portion of the first line end of the insulation feature is surrounded by the first vertically-extending dielectric structure; and an upper portion of the second line end of the insulation feature is surrounded by the second vertically-extending dielectric structure.

In certain embodiments of the semiconductor structure, the first gate structure and the second gate structure extend upward in a vertical direction perpendicular to the lateral Y-direction and the lateral X-direction to uppermost surfaces defining a gate top plane; the first vertically-extending dielectric structure and the second vertically-extending dielectric structure each have an uppermost surface; the first vertically-extending dielectric structure and the second vertically-extending dielectric structure each have a first thickness in the lateral Y-direction at the gate top plane; the first vertically-extending dielectric structure and the second vertically-extending dielectric structure each have a second thickness in the lateral Y-direction at the respective uppermost surface; and for each vertically-extending dielectric structure, the second thickness is greater than the first thickness.

In certain embodiments of the semiconductor structure, the first gate structure and the second gate structure extend upward in a vertical direction perpendicular to the lateral Y-direction and the lateral X-direction to uppermost surfaces defining a gate top plane; the insulation feature has an uppermost surface; the insulation feature has a first thickness in the lateral Y-direction at the gate top plane; the insulation feature has a second thickness in the lateral Y-direction at the uppermost surface; and the second thickness is greater than or equal to the first thickness.

In certain embodiments, the semiconductor structure further includes at last one vertically-extending dielectric structure, each at least one vertically-extending dielectric structure extends in the lateral X-direction; the first line end of the insulation feature is distanced from each at least one vertically-extending dielectric structure by a non-zero distance; and the second line end of the insulation feature is distanced from each at least one vertically-extending dielectric structure by a non-zero distance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a structure including a substrate, fins overlying the substrate, a gate segment overlying the fins and extending in a first lateral direction from a first end to a second end, a dielectric layer segment overlying the gate segment and contacting the gate segment at an interface height, a first vertically-extending dielectric structure having a first inner surface abutting the first end of the gate segment, and a second vertically-extending dielectric structure having a second inner surface abutting the second end of the gate segment, wherein the inner surfaces are inclined toward or parallel to one another from a bottom end to a top end;
performing an etch process to remove the dielectric layer segment, wherein the etch process etches the inner surfaces of the vertically-extending dielectric structures such that a minimum distance between the vertically-extending dielectric structures is established at the interface height;
removing the gate segment and the fins located below the gate segment to form a cavity; and
forming an insulation feature in the cavity, wherein the insulation feature extends in the first lateral direction from a first line end to a second line end, wherein the first line end contacts the first vertically-extending dielectric structure, and wherein the second line end contacts the second vertically-extending dielectric structure.

2. The method of claim 1, wherein forming the insulation feature in the cavity comprises:
depositing an insulation material in the cavity; and
performing a planarization process to remove an overburden portion of the insulation material.

3. The method of claim 2, wherein the planarization process to remove an overburden portion of the insulation material forms an upper surface of the structure, and wherein at the upper surface no portion of the dielectric layer segment is present.

4. The method of claim 3, wherein:
a remaining gate segment is located adjacent to the insulation feature;
a remaining dielectric layer segment is located over the remaining gate segment;
the upper surface of the structure is formed by the insulation feature and the remaining dielectric layer segment;
the method further comprises removing the remaining dielectric layer segment; and
after removing the remaining dielectric layer segment, the insulation feature and the vertically-extending dielectric structures remain in direct contact at the upper surface.

5. The method of claim 4, wherein:
after forming the structure, a source/drain feature is spaced from the gate segment in a second lateral direction perpendicular to the first lateral direction, an interlayer dielectric (ILD) structure is located over the source/drain feature, and a cap is located over the ILD structure; and
the method further comprises:
after removing the remaining dielectric layer segment, depositing an additional dielectric material over the structure;
performing an additional planarization process to remove the cap, wherein a remaining portion of the additional dielectric material remains over the remaining gate segment;
removing the ILD structure; and
forming a conductive contact in contact with the source/drain feature.

6. The method of claim 1, wherein the etch process forms each inner surface at the interface height at an internal angle to a horizontal line, when each internal angle is at least 90 degrees.

7. The method of claim 1, wherein:
the insulation feature is formed with an upper portion;
the upper portion has a belted shape with a lower end having a lower thickness in the first lateral direction, a middle at the interface height having a middle thickness in the first lateral direction, and an upper end having an upper thickness in the first lateral direction; and
the middle thickness is less than the lower thickness and is less than the upper thickness.

8. The method of claim 1, wherein:
the insulation feature has an uppermost surface;
the insulation feature has a first thickness in the first lateral direction at the interface height;
the insulation feature has a second thickness in the first lateral direction at the uppermost surface; and
the second thickness is greater than the first thickness.

9. The method of claim 1, wherein performing the etch process to remove the dielectric layer segment etches the inner surfaces of the vertically-extending dielectric structures such that the inner surfaces are vertical.

10. A method comprising:
forming a structure including a substrate, fins overlying the substrate and extending in a lateral X-direction, a gate structure overlying the fins and extending in a lateral Y-direction perpendicular to the lateral X-direction, a dielectric layer overlying the gate structure, and at least one vertically-extending dielectric structure cutting through the dielectric layer and the gate structure;
performing an etch process to remove a selected portion of the dielectric layer to form an opening, wherein the opening does not contact the at least one vertically-extending dielectric structure;
removing a portion of the gate structure located below the opening and the fins located below the opening to form a cavity; and
forming an insulation feature in the cavity.

11. The method of claim 10, wherein the insulation feature is distanced from each at least one vertically-extending dielectric structure by a non-zero distance.

12. The method of claim 10, wherein forming the insulation feature in the cavity comprises:
depositing an insulation material in the cavity; and
performing a planarization process to remove an overburden portion of the insulation material.

13. The method of claim 12, wherein:
an upper surface of the structure is formed by the insulation feature and a remaining portion of the dielectric layer;
the method further comprises removing the remaining portion of the dielectric layer; and
after removing the remaining portion of the dielectric layer, upper portions of sidewalls of the insulation feature are uncovered.

14. The method of claim 13, wherein:
after forming the structure, a source/drain feature is spaced from the gate structure in the lateral X-direction, an interlayer dielectric (ILD) structure is located over the source/drain feature, and a cap is located over the ILD structure; and
the method further comprises:
after removing the remaining portion of the dielectric layer, depositing an additional dielectric material over the structure;
performing an additional planarization process to remove the cap, wherein a remaining portion of the additional dielectric material remains over a remaining portion of the gate structure;
removing the ILD structure; and
forming a conductive contact in contact with the source/drain feature.

15. The method of claim 14, wherein the insulation feature extends in the lateral Y-direction from a first line end to a second line end, wherein the first line end contacts a first portion of the additional dielectric material, and wherein the second line end contacts a second portion of the additional dielectric material.

16. A semiconductor structure comprising:
a first gate structure and a second gate structure distanced from one another in a lateral Y-direction, wherein each gate structure extends in a lateral X-direction perpendicular to the lateral Y-direction;
an insulation feature distanced from the first gate structure and the second gate structure in the lateral Y-direction, wherein the insulation feature extends in the lateral X-direction from a first line end to a second line end;
a first conductive contact located between the first gate structure and the insulation feature and a second conductive contact located between the second gate structure and the insulation feature; wherein:
each conductive contact extends in the lateral Y-direction, terminates at a first contact end, and terminates at a second contact end;
the first contact ends define a first vertical plane that intersects the insulation feature; and
the second contact ends define a second vertical plane that intersects the insulation feature.

17. The semiconductor structure of claim 16, further comprising a first vertically-extending dielectric structure and a second vertically-extending dielectric structure, wherein:
the first vertically-extending dielectric structure and the second vertically-extending dielectric structure extend in the lateral X-direction and are distanced from one another in the lateral Y-direction;
an upper portion of the first line end of the insulation feature is surrounded by the first vertically-extending dielectric structure; and
an upper portion of the second line end of the insulation feature is surrounded by the second vertically-extending dielectric structure.

18. The semiconductor structure of claim 17, wherein:
the first gate structure and the second gate structure extend upward in a vertical direction perpendicular to the lateral Y-direction and the lateral X-direction to uppermost surfaces defining a gate top plane;
the first vertically-extending dielectric structure and the second vertically-extending dielectric structure each have an uppermost surface;
the first vertically-extending dielectric structure and the second vertically-extending dielectric structure each have a first thickness in the lateral Y-direction at the gate top plane;
the first vertically-extending dielectric structure and the second vertically-extending dielectric structure each have a second thickness in the lateral Y-direction at the respective uppermost surface; and
for each vertically-extending dielectric structure, the second thickness is greater than the first thickness.

19. The semiconductor structure of claim 17, wherein:
the first gate structure and the second gate structure extend upward in a vertical direction perpendicular to the lateral Y-direction and the lateral X-direction to uppermost surfaces defining a gate top plane;
the insulation feature has an uppermost surface;
the insulation feature has a first thickness in the lateral Y-direction at the gate top plane;
the insulation feature has a second thickness in the lateral Y-direction at the uppermost surface; and
the second thickness is greater than or equal to the first thickness.

20. The semiconductor structure of claim 16, further comprising at last one vertically-extending dielectric structure, wherein:
each at least one vertically-extending dielectric structure extends in the lateral X-direction;
the first line end of the insulation feature is distanced from each at least one vertically-extending dielectric structure by a non-zero distance; and
the second line end of the insulation feature is distanced from each at least one vertically-extending dielectric structure by a non-zero distance.
